(19) United States
(12) Patent Application Publication
(10) Pub. No.: US 2026/0013298 A1
(43) Pub. Date: Jan. 8, 2026

(54) DISPLAY APPARATUS

(71) Applicant: LG Display Co., Ltd., Seoul (KR)

(72) Inventors: TaeYoon KIM, Seoul (KR); HyeSun JUNG, Seoul (KR); BungGoo KIM, Paju-si (KR); HyoungHo AHN, Paju-si (KR); HeeWon LEE, Paju-si (KR); JunYoung JO, Paju-si (KR)

(73) Assignee: LG Display Co., Ltd., Seoul (KR)

(21) Appl. No.: 19/224,095

(22) Filed: May 30, 2025

(30) Foreign Application Priority Data
Jul. 2, 2024 (KR) 10-2024-0087064

(51) Int. Cl. H10H 29/49; H01L 25/16; H10H 29/41

(52) U.S. Cl. CPC H10H 29/49; H01L 25/167; H10H 29/41

(57) ABSTRACT

A display apparatus in some examples can include a substrate having an active area and a non-active area, a first non-active area enclosing the active area, a bending area extending from the first non-active area, a second non-active area extending from the bending area and having a plurality of pad electrodes disposed therein, a pixel driving circuit disposed on the substrate and electrically connected to the plurality of pad electrodes, a plurality of insulating layers disposed on the pixel driving circuit, and a plurality of micro LEDs disposed on the plurality of insulating layers. A pressure applied to the connection line when the flexible circuit board is bonded is minimized or reduced and a pressure margin for bonding the pad electrodes and the flexible circuit board can be ensured.

### CROSS-REFERENCE TO RELATED APPLICATIONS

This application claims priority to Korean Patent Application No. 10-2024-0087064 filed on Jul. 2, 2024, in the Korean Intellectual Property Office, the entire disclosure of which is hereby expressly incorporated by reference into the present application.

### BACKGROUND

### Field

The present disclosure relates to an apparatus and particularly to, for example, without limitation, a display apparatus.

### Discussion of the Related Art

Display apparatuses are being applied to various electronic devices, such as TVs, mobile phones, laptops, and tablets.

Among the display apparatuses, there are an organic light emitting display (OLED) apparatus which is a self-emitting device and a liquid crystal display (LCD) apparatus which requires a separate light source.

Recently, a display apparatus including a light emitting diode (LED) is attracting attention as a next generation display apparatus. The light emitting diode is formed of an inorganic material, rather than an organic material so that lighting speed is faster, a luminous efficiency is excellent, and an image with a higher luminance is displayed, as compared with the liquid crystal display apparatus or the organic light emitting display apparatus.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

An object to be achieved by the present disclosure is to provide a display apparatus in which a pressure applied to a connection line when a flexible circuit board is bonded is minimized or reduced.

An object to be achieved by the present disclosure is to provide a display apparatus in which a margin of a pressure applied when a flexible circuit board is bonded is ensured.

An object to be achieved by the present disclosure is to provide a display apparatus in which the lifting of a connection line due to a pressure applied when a flexible circuit board is bonded is minimized or reduced.

An object to be achieved by the present disclosure is to provide a display apparatus which is driven at a low power in terms of reduction of power consumption by improving reliability by minimizing bubbles and permeation of moisture or oxygen due to the lifting of the connection line.

Objects of the present disclosure are not limited to the above-mentioned objects, and other objects, which are not mentioned above, can be clearly understood by those skilled in the art from the following descriptions.

According to an aspect of the present disclosure, a display apparatus includes: a substrate which has an active area and a non-active area including a first non-active area enclosing the active area, a bending area extending from the first non-active area, and a second non-active area extending from the bending area and having a plurality of pad electrodes disposed therein; a pixel driving circuit which is disposed on the substrate and is electrically connected to the plurality of pad electrodes; a plurality of insulating layers disposed on the pixel driving circuit; and a plurality of micro LEDs which is disposed on the plurality of insulating layers in the active area to be electrically connected to the pixel driving circuit. The plurality of insulating layers can be disposed in an area other than the second non-active area. Accordingly, a pressure applied to the connection line when the flexible circuit board is bonded is minimized or reduced and a pressure margin for bonding the plurality of pad electrodes and the flexible circuit board can be ensured.

According to another aspect of the present disclosure, there is provided a display apparatus. The display apparatus includes a substrate which has an active area and a non-active area including a first non-active area enclosing the active area, a bending area extending from the first non-active area, and a second non-active area extending from the bending area and having a plurality of pad electrodes disposed therein, a pixel driving circuit which is disposed on the substrate and is electrically connected to the plurality of pad electrodes, a plurality of insulating layers disposed on the pixel driving circuit, a plurality of micro LEDs which is disposed on the plurality of insulating layers in the active area to be electrically connected to the pixel driving circuit, and a plurality of connection lines which is disposed on the pixel driving circuit and is electrically connected to the pixel driving circuit. The plurality of insulating layers can be disposed in an area other than the second non-active area.

Other detailed matters of the example embodiments of the present disclosure are included in the detailed description and drawings.

According to aspects of the present disclosure, a pressure margin for bonding a plurality of pad electrodes and a flexible circuit board is ensured to improve electrical connection of the plurality of pad electrodes and the flexible circuit board.

According to aspects of the present disclosure, an insulating layer between the plurality of pad electrodes and the plurality of second connection lines is removed to minimize or reduce a pressure applied to the plurality of second connection lines.

According to aspects of the present disclosure, the lifting of the plurality of second connection lines due to the pressure is suppressed to minimize or reduce permeation of moisture or oxygen, thereby improving the reliability of the display apparatus.

According to aspects of the present disclosure, bubbles generated due to the lifting of the plurality of second connection lines are suppressed to minimize or reduce a potential defect and improve the lifespan of the display apparatus, to be driven at a low power in terms of reduction of a power consumption.

The effects According to aspects of the present disclosure are not limited to the contents exemplified above, and more various effects are included in the present specification.

It is to be understood that both the foregoing general description and the following detailed description are example and explanatory and are intended to provide further explanation of the inventive concepts as claimed.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an example embodiment of the present disclosure;

FIG. 2 is a plan view of a display apparatus according to an example embodiment of the present disclosure;

FIG. 3 is an enlarged view of a display apparatus according to an example embodiment of the present disclosure;

FIG. 4 is a view illustrating a circuit structure according to an example embodiment of the present disclosure;

FIG. 5 is a plan view of a display apparatus according to an example embodiment of the present disclosure;

FIG. 6 is a plan view of a display apparatus according to an example embodiment of the present disclosure;

FIG. 7 is a plan view of a display apparatus according to an example embodiment of the present disclosure;

FIG. 8 is a cross-sectional view taken along VIII-VIII′ of FIG. 3;

FIG. 9 is a cross-sectional view of a display apparatus according to an example embodiment of the present disclosure;

FIG. 10 is a cross-sectional view of a display apparatus according to another example embodiment of the present disclosure; and

FIGS. 11 to 14 are views illustrating devices to which a display apparatus according to example embodiments of the present disclosure is applied.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Advantages and characteristics of the present disclosure and a method of achieving the advantages and characteristics will be clear by referring to example embodiments of the present disclosure described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When explaining temporal relationships, terms such as “after,” “following,” “subsequent to,” or “before,” etc., can include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) can be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component can be directly connected, coupled, joined, or attached to the other component, but unless explicitly specified otherwise, it can also be indirectly connected, coupled, joined, or attached with another component intervening between each component.

When a component or layer is described as being “in contact with” or “overlapping” another component or layer, the component or layer can directly contact or overlap the other component or layer, but unless explicitly specified otherwise, it should be understood that it can also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The terms “first direction”, “second direction”, “third direction”, “X-axis direction”, “Y-axis direction”, and “Z-axis direction” should not be interpreted solely as geometric relationships perpendicular to each other, but can indicate broader directionality within the range where the configuration of the present disclosure can function. Further, the term “can” fully encompasses all the meanings and coverages of the term “may” and vice versa.

The features of various embodiments in the present disclosure can be partially or wholly combined or associated with each other, various technical interlocking and operations are possible, and each embodiment can be implemented independently of each other or can be implemented together in an associated relationship.

Any implementation described herein as an “example” is not necessarily to be construed as preferred or advantageous over other implementations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments can be provided so that this disclosure can be sufficiently thorough and complete to assist those skilled in the art to fully understand the scope of the present disclosure.

Hereinafter, a display apparatus according to example embodiments of the present disclosure will be described in detail with reference to accompanying drawings. All the components of each display apparatus according to all embodiments of the present disclosure are operatively coupled and configured.

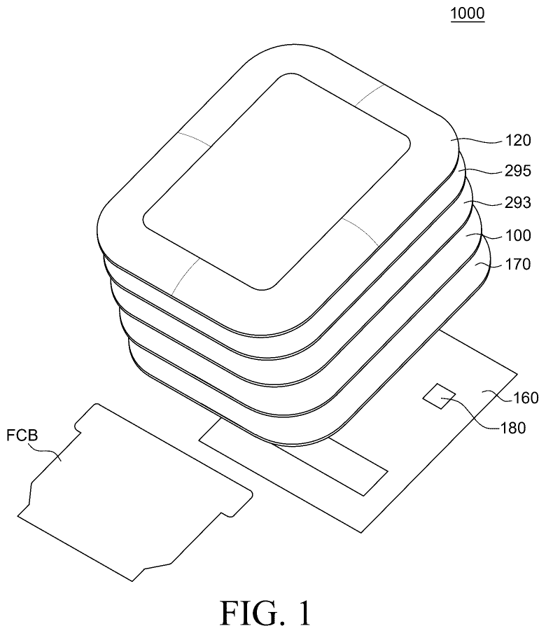

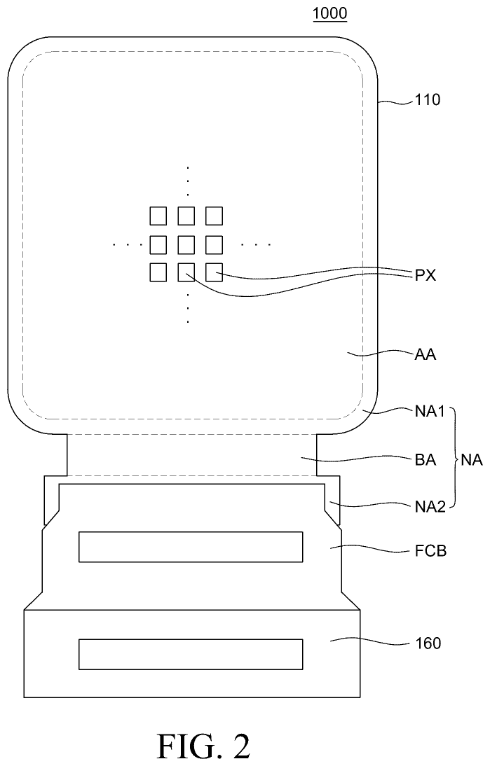

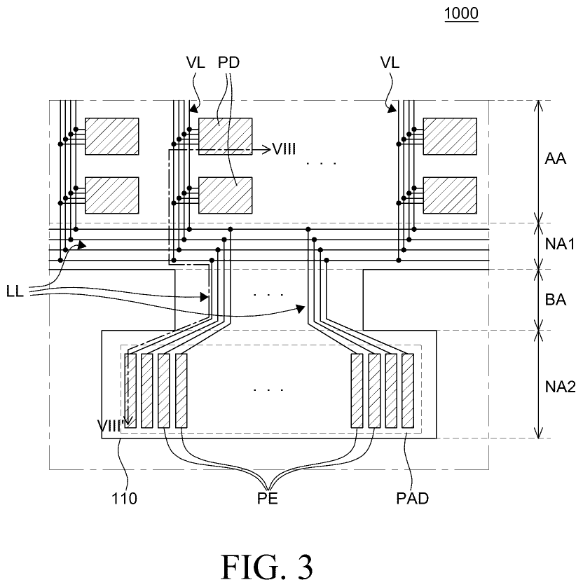

FIG. 1 is a perspective view illustrating a display apparatus according to an example embodiment of the present disclosure. FIG. 2 is a plan view of a display apparatus according to an example embodiment of the present disclosure. FIG. 3 is an enlarged view of a display apparatus according to an example embodiment of the present disclosure.

Referring to FIGS. 1 to 3, a display apparatus 1000 according to an example embodiment of the present disclosure can include a display panel 100, a polarization layer 293, an adhesive layer 295, a cover member 120, a support substrate 140, a flexible circuit board FCB, and a printed circuit board 160.

For example, the display panel 100 of the display apparatus 1000 can include a substrate 110. The substrate 110 can be a member which supports other components of the display apparatus 1000. The substrate 110 can be formed of an insulating material. For example, the substrate 110 can be formed of glass or resin. Further, the substrate 110 can also be formed of a material having flexibility. For example, the substrate 110 can be formed of a plastic material having flexibility, such as polyimide (PI), but the example embodiments of the present disclosure are not limited thereto.

The display panel 100 can implement information, videos, and/or images which are provided to users. For example, the display panel 100 can include an active area AA and a non-active area NA. For example, the substrate 110 can include an active area AA and a non-active area NA. However, the active area AA and the non-active area NA are not mentioned to be limited to the substrate 110, but can be mentioned for the entire display apparatus 1000.

The active area AA can be an area where images are displayed. The active area AA can include a plurality of pixels PX. Each of the plurality of pixels PX can be configured by a plurality of sub pixels. A plurality of micro LEDs can be disposed in each of the plurality of sub pixels. The plurality of micro LEDs can be configured in different manners depending on the type of the display apparatus 1000. For example, if the display apparatus 1000 is an inorganic light emitting display apparatus, the micro LEDs can be a micro light emitting diode, but the example embodiments of the present disclosure are not limited thereto.

The non-active area NA can be an area where no image is displayed. In the non-active area NA, various wiring lines and circuits for driving the plurality of pixels PX of the active area AA can be disposed. For example, in the non-active area NA, various wiring lines and driving circuits can be mounted and a pad unit PAD to which an integrated circuit and a printed circuit are connected can be disposed, but the example embodiments of the present disclosure are not limited thereto.

For example, the driving circuit can be a data driving circuit and/or a gate driving circuit, but the example embodiments of the present disclosure are not limited thereto. Wiring lines through which a control signal for controlling driving circuits is supplied can be disposed. For example, the control signal can include various timing signals including a clock signal, an input data enable signal, and synchronization signals, but the example embodiments of the present disclosure are not limited thereto. The control signal can be received through the pad unit PAD. For example, in the non-active area NA, link lines LL can be disposed to transmit signals. For example, driving components, such as the flexible circuit board FCB and the printed circuit board 160, can be connected to the pad unit PAD.

According to aspects of the present disclosure, the non-active area NA can include a first non-active area NA1, a bending area BA, and a second non-active area NA2. For example, the first non-active area NA1 can be an area which encloses at least a part of the active area AA. The bending area BA can be an area extending from at least one side, among a plurality of sides of the first non-active area NA1 and can be a bendable area. The second non-active area NA2 can be an area extending from the bending area BA and the pad unit PAD can be disposed therein. For example, the bending area BA can be in a bent state and the other areas of the substrate 110 excluding the bending area BA can be in a flat state. In this case, as the bending area BA is bent, the second non-active area NA2 can be located on a rear surface of the active area AA, but the example embodiments of the present disclosure are not limited thereto.

The active area AA of the substrate 110 or the display apparatus 1000 can be configured with various shapes depending on a design of the display apparatus 1000. For example, the active area AA can be configured with a rectangular shape formed with four rounded corners, but the example embodiments of the present disclosure are not limited thereto. As another example, the active area AA can be configured with a rectangular shape formed with four right-angled corners or a circular shape, but the example embodiments of the present disclosure are not limited thereto.

According to aspects of the present disclosure, a width of the second non-active area NA2 in which the plurality of pad electrodes PE is disposed can be larger than a width of the bending area BA in which only a plurality of link lines LL is disposed. Further, a width of the active area AA in which the plurality of sub pixels is disposed can be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example embodiments of the present disclosure are not limited thereto.

Referring to FIG. 3, a plurality of pixel driving circuits PD can be disposed in the active area AA. The plurality of pixel driving circuits PD can be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD can include a power line and a signal line for controlling emission on/off of the micro LED and/or an emission time. For example, the plurality of pixel driving circuits PD can be driving drivers manufactured using a metal-oxide-silicon field effect transistor (MOSFET) manufacturing process on a semiconductor substrate, but the example embodiments of the present disclosure are not limited thereto. The driving driver includes a plurality of pixel driving circuits PD and can drive a plurality of sub pixels.

Referring to FIG. 1 together, the flexible circuit board FCB and the printed circuit board 160 can be disposed below the display panel 100. The flexible circuit board FCB and the printed circuit board 160 can be disposed at least at one edge of the display panel 100, but the example embodiments of the present disclosure are not limited thereto. One side of the flexible circuit board FCB can be attached to the display panel 100 and the other side can be attached to the printed circuit board 160, but the example embodiments of the present disclosure are not limited thereto. The flexible circuit board FCB can be a flexible film, but the example embodiments of the present disclosure are not limited thereto.

A pad unit PAD including a plurality of pad electrodes PE can be disposed in the second non-active area NA2. In the pad unit PAD, a driving component including one or more flexible circuit boards (or flexible films) FCB and the printed circuit board 160 can be attached or bonded. The plurality of pad electrodes PE of the pad unit PAD can be electrically connected to one or more flexible circuit boards (or flexible films) FCB and transmit various signals (or powers) from the printed circuit board 160 and the flexible circuit board (or a flexible film) FCB to the plurality of pixel driving circuits PD of the active area AA.

The flexible circuit board (or flexible film) FCB can be a film on which various components are disposed on a base film having ductility. For example, driving ICs such as a gate driver IC or a data driver IC can be disposed in the flexible circuit board (or flexible film) FCB, but the example embodiments of the present disclosure are not limited thereto. The driving IC can be a component which processes data and driving signals to display images. The driving IC can be disposed by a chip on glass (COG), a chip on film (COF), or a tape carrier package (TCP) technique depending on a mounting method, but the example embodiments of the present disclosure are not limited thereto. The flexible circuit board (or flexible film) FCB can be attached or bonded onto the plurality of pad electrodes PE through a conductive adhesive layer, but the example embodiments of the present disclosure are not limited thereto.

The printed circuit board 160 can be a component which is electrically connected to one or more flexible circuit boards (or flexible films) FCB and supplies a signal to the driving IC. The printed circuit board 160 is disposed at one side of the flexible circuit board (or flexible film) FCB to be electrically connected to the flexible circuit board (or flexible film) FCB. On the printed circuit board 160, various components for supplying various signals to the driving IC can be disposed. For example, on the printed circuit board 160, various components, such as a timing controller, a power source, a memory, or a processor, can be disposed. For example, the printed circuit board 160 can include a power management integrated circuit (PMIC), but the example embodiments of the present disclosure are not limited thereto.

The printed circuit board 160 can include at least one hole 180, but the example embodiments of the present disclosure are not limited thereto. An internal component which senses ambient light or temperature to be supplied to a plurality of sensors can be disposed in an area corresponding to at least one hole 180. For example, the internal component can include an ambient light sensor (ALS) or a temperature sensor, but the example embodiments of the present disclosure are not limited thereto. For example, the hole 180 can be a transmission hole, but the example embodiments of the present disclosure are not limited thereto.

A polarization layer 293 can be disposed on the display panel 100. The polarization layer 293 can suppress or reduce the influence on the micro LED caused by light generated from an external light source and entering the display panel 100.

A cover member 120 can be disposed on the polarization layer 293. The cover member 120 can be a member for protecting the display panel 100. The adhesive layer 295 can be disposed between the polarization layer 293 and the cover member 120. The cover member 120 can be attached to the display panel 100 using the adhesive layer 295. The adhesive layer 295 can include an optically clear adhesive (OCA), an optically clear resin (OCR), or a pressure sensitive adhesive (PSA), but the example embodiments of the present disclosure are not limited thereto.

The support substrate 140 can be disposed between the display panel 100 and the printed circuit board 160. The support substrate 140 can reinforce a rigidity of the display panel 100. The support substrate 140 can be a back plate, but the example embodiments of the present disclosure are not limited thereto.

Referring to FIGS. 1 to 3, the plurality of link lines LL can be disposed in the non-active area NA. The plurality of link lines LL can be wiring lines which transmit various signals from one or more flexible circuit boards (or flexible films) FCB and the printed circuit board 160 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) FCB and the printed circuit board 160 through the driving line VL of the active area AA and the link line LL of the non-active area NA to be driven.

For example, the plurality of driving lines VL can be wiring lines for transmitting a signal output from the flexible circuit board (or flexible film) FCB and the printed circuit board 160 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) FCB and the printed circuit board 160 can be transmitted to each of the plurality of pixel driving circuits PD through the plurality of link lines LL and the plurality of driving lines VL.

As the bending area BA is bent, a part of the plurality of link lines LL can be bent together. A stress is concentrated in the bent part of the link line LL, which causes a crack on the link line LL. Accordingly, the plurality of link lines LL can be configured by a conductive material having excellent ductility to reduce the crack caused when the bending area BA is bent. For example, the plurality of link lines LL can be configured by a conductive material having excellent ductility, such as gold (Au), silver (Ag), or aluminum (Al), but the example embodiments of the present disclosure are not limited thereto. Further, the plurality of link lines LL can be configured by one of various conductive materials used for the active area AA. For example, the plurality of link lines LL can be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto. The plurality of link lines LL can be configured by a multi-layered structure including various conductive materials. For example, the plurality of link lines LL can be configured with a triple-layered structure of titanium (Ti)/aluminum (Al)/titanium (Ti), but the example embodiments of the present disclosure are not limited thereto.

The plurality of link lines LL can be configured with various shapes to reduce a stress. At least some of the plurality of link lines LL disposed on the bending area BA can extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA can extend in an inclined direction from one direction. As another example, at least some of the plurality of link lines LL can be configured by various shapes of patterns. For example, at least some of the plurality of link lines LL disposed on the bending area BA can have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the example embodiments of the present disclosure are not limited thereto. Accordingly, in order to minimize or reduce a stress concentrated on the plurality of link lines LL and a crack caused thereby, a shape of the plurality of link lines LL can be various shapes including the above-mentioned shapes, but the example embodiments of the present disclosure are not limited thereto.

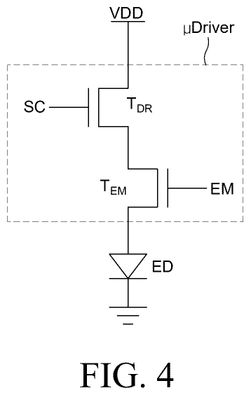

FIG. 4 is a view illustrating a circuit structure according to an example embodiment of the present disclosure.

A pixel driving circuit PD can include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), the present disclosure is not limited thereto. For example, eight micro LEDs (ED) can be connected to one micro driver (μDriver). As another example, 16 micro LEDs (ED) can be connected to one micro driver (μDriver) or 32 micro LEDs (ED) or 64 micro LEDs (ED) can be simultaneously connected to one micro driver (μDriver). The micro LED (ED) can be a micro LED (μLED).

One micro driver (μDriver) can include a driving transistor TDR and an emission transistor T_{EM}, but the example embodiments of the present disclosure are not limited thereto.

For example, a high potential power voltage VDD can be applied to a first electrode of the driving transistor TDR and a first electrode of the emission transistor T_{EM} can be connected to a second electrode, and a scan signal SC can be applied to a gate electrode. The scan signal SC applied to the gate electrode of the driving transistor TDR is a direct current (DC) power and a fixed reference voltage can be applied in every frame, but the example embodiments of the present disclosure are not limited thereto.

The second electrode of the driving transistor TDR can be connected to a first electrode of the emission transistor T_{EM}, the micro LED (ED) can be connected to a second electrode, and the emission signal EM can be applied to a gate electrode. The emission signal EM applied to the gate electrode of the emission transistor T_{EM} can be a pulse width modulation signal which changes in every frame, but the example embodiments of the present disclosure are not limited thereto.

A first electrode of the micro LED (ED) can be connected to the second electrode of the emission transistor T_{EM} and a second electrode can be connected to the ground. For example, the first electrode can be an anode electrode and the second electrode can be a cathode electrode, but the example embodiments of the present disclosure are not limited thereto.

Each of the driving transistor TDR and the emission transistor T_{EM} can be an n-type transistor or a p-type transistor.

The driving transistor T_{DR} can be turned on by a scan signal SC applied from the timing controller T-CON to the micro driver (μDriver) and the emission transistor T_{EM} can be turned on by the emission signal EM. By doing this, the driving current is applied to the micro LED (ED) via the driving transistor T_{DR} and the emission transistor T_{EM} by the high potential power voltage VDD applied to the first electrode of the driving transistor T_{DR} so that the micro LED (ED) can emit light.

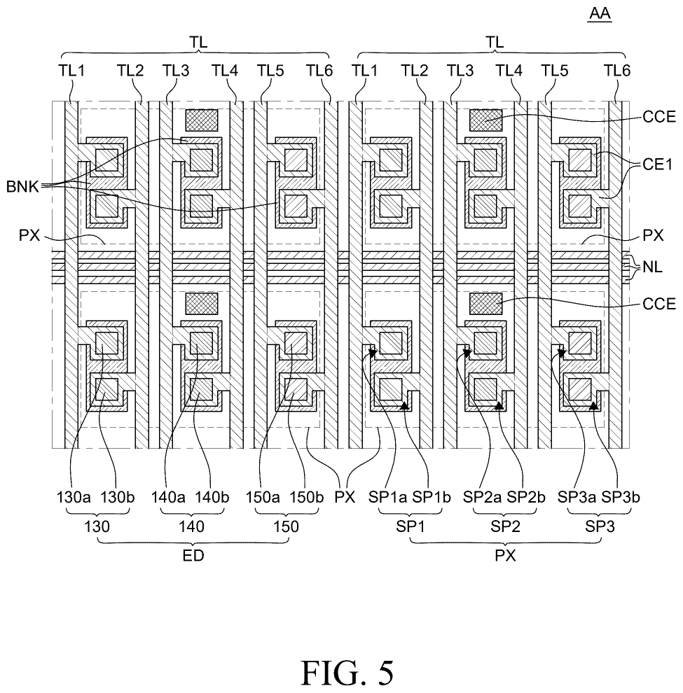

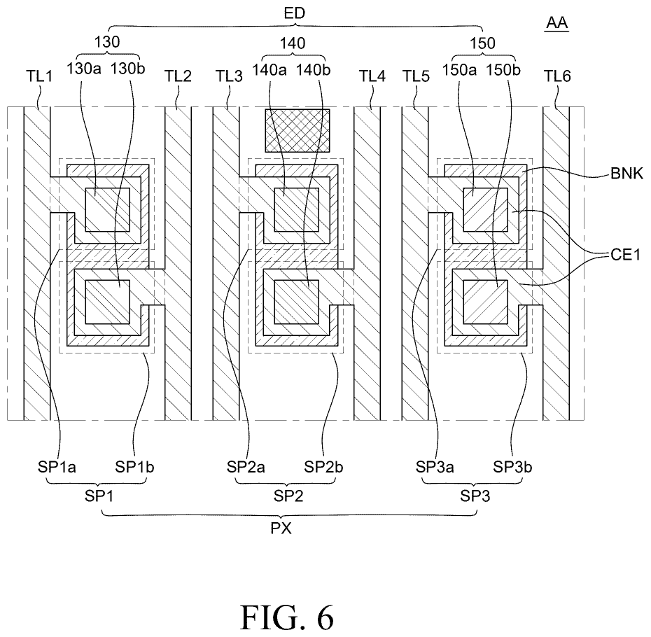

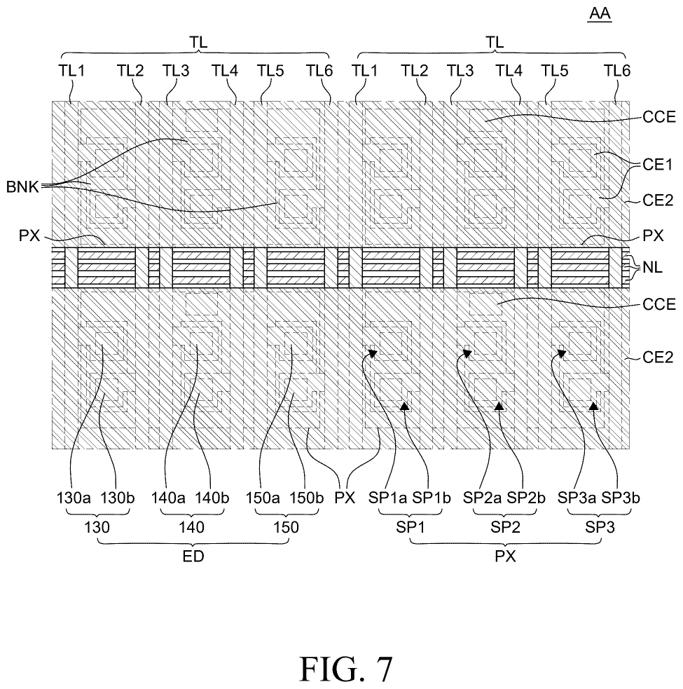

FIGS. 5 to 7 are plan views of a display apparatus according to an example embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, a plurality of signal lines TL, a plurality of communication lines NL, a plurality of first electrodes CE1, a plurality of banks BNK, and a plurality of micro LEDs (ED) are illustrated, but the example embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which is configured by a plurality of sub pixels can be disposed in the active area AA. Each of the plurality of sub pixels includes a micro LED (ED) and can independently emit light. The plurality of sub pixels can be disposed in a matrix by forming a plurality of rows and a plurality of columns, but the example embodiments of the present disclosure are not limited thereto.

The plurality of sub pixels can include a first sub pixel SP1, a second sub pixel SP2, and a third sub pixel SP3. For example, any one of the first sub pixel SP1, the second sub pixel SP2, and the third sub pixel SP3 can be a red sub pixel, another can be a green sub pixel, and the third can be a blue sub pixel. The types of the plurality of sub pixels are illustrative, but the example embodiments of the present disclosure are not limited thereto.

Each of the plurality of pixels PX can include one or more first sub pixels SP1, one or more second sub pixels SP2, and one or more third sub pixels SP3. For example, one pixel PX can include one pair of first sub pixels SP1, one pair of second sub pixels SP2, and one pair of third sub pixels SP3. One pair of first sub pixels SP1 can be configured by a 1-1-th sub pixel SP1a and a 1-2-th sub pixel SP1b. One pair of second sub pixels SP2 can be configured by a 2-1-th sub pixel SP2a and a 2-2-th sub pixel SP2b. One pair of third sub pixels SP3 can be configured by a 3-1-th sub pixel SP3a and a 3-2-th sub pixel SP3b. For example, one pixel PX can include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example embodiments of the present disclosure are not limited thereto.

The plurality of sub pixels which forms one pixel PX can be disposed in various ways. For example, in one pixel PX, one pair of first sub pixels SP1 can be disposed on the same column, one pair of second sub pixels SP2 can be disposed on the same column, and one pair of third sub pixels SP3 can be disposed on the same column. The first sub pixels SP1, the second sub pixels SP2, and the third sub pixels SP3 can be disposed on the same row. The number and a placement of the plurality of sub pixels which configures one pixel PX are illustrative, but the example embodiments of the present disclosure are not limited thereto.

The plurality of signal lines TL can be disposed in an area between the plurality of sub pixels. The plurality of signal lines TL can extend in the column direction between the plurality of sub pixels. The plurality of signal lines TL can be wiring lines which transmit an anode voltage from the pixel driving circuit PD to the plurality of sub pixels. For example, the plurality of signal lines TL can be electrically connected to the plurality of pixel driving circuits PD and the first electrodes CE1 of the plurality of sub pixels. The anode voltage output from the pixel driving circuit PD can be transmitted to the first electrode CE1 of the plurality of sub pixels through the plurality of signal lines TL. For example, the first electrode CE1 can be an electrode which is electrically connected to the anode electrode 134 of the micro LED (ED). Therefore, the anode voltage from the signal line TL can be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving is possible.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to one pair of first sub pixels SP1, respectively. The third signal line TL3 and the fourth signal line TLA can be electrically connected to one pair of second sub pixels SP2, respectively. The fifth signal line TL5 and the sixth signal line TL6 can be electrically connected to one pair of third sub pixels SP3, respectively.

The first signal line TL1 can be disposed on one of one pair of first sub pixels SP1 and the second signal line TL2 can be disposed on the other one of one pair of first sub pixels SP1. The first signal line TL1 can be electrically connected to one first sub pixel SP1, between one pair of first sub pixels SP1, for example, to the first electrode CE1 of the 1-1-th sub pixel SP1a. The second signal line TL2 can be electrically connected to the other first sub pixel SP1, between one pair of first sub pixels SP1, for example, to the first electrode CE1 of the 1-2-th sub pixel SP1b.

The third signal line TL3 can be disposed on one of one pair of second sub pixels SP2 and the fourth signal line TLA can be disposed on the other one of one pair of second sub pixels SP2. For example, the third signal line TL3 can be disposed to be adjacent to the second signal line TL2. The third signal line TL3 can be electrically connected to one second sub pixel SP2, between one pair of second sub pixels SP2, for example, to the first electrode CE1 of the 2-1-th sub pixel SP2a. The fourth signal line TLA can be electrically connected to the other second sub pixel SP2, between one pair of second sub pixels SP2, for example, to the first electrode CE1 of the 2-2-th sub pixel SP2b.

The fifth signal line TL5 can be disposed on one of one pair of third sub pixels SP3 and the sixth signal line TL6 can be disposed on the other one of one pair of third sub pixels SP3. For example, the fifth signal line TL5 can be disposed to be adjacent to the fourth signal line TL4. The sixth signal line TL6 can be disposed to be adjacent to the first signal line TL1 connected to the adjacent pixel PX. The fifth signal line TL5 can be electrically connected to one third sub pixel SP3, between one pair of third sub pixels SP3, for example, to the first electrode CE1 of the 3-1-th sub pixel SP3a. The sixth signal line TL6 can be electrically connected to the other third sub pixel SP3, between one pair of third sub pixels SP3, for example, to the first electrode CE1 of the 3-2-th sub pixel SP3b.

The plurality of signal lines TL can be formed of a conductive material. For example, the plurality of signal lines TL can be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the plurality of signal lines TL can be formed with a multi-layered structure of conductive materials. For example, the plurality of signal lines TL can be formed with a multi-layered structure of titanium (Ti)/aluminum (Al)/titanium (Ti)/indium tin oxide (ITO), but the example embodiments of the present disclosure are not limited thereto.

A plurality of communication lines NL can be disposed in an area between the plurality of pixels PX. The plurality of communication lines NL can be disposed to extend in the row direction in an area between the plurality of pixels PX. The plurality of communication lines NL can be disposed in the area between the plurality of second electrodes CE2 and may not overlap the plurality of second electrodes CE2. For example, the plurality of communication lines NL can be wiring lines used for short distance communication, such as near field communication (NFC). The plurality of communication lines NL can serve as antennas. For example, the plurality of communication lines NL can be a plurality of connection lines, but the example embodiments of the present disclosure are not limited thereto.

According to aspects of the present disclosure, a bank BNK can be disposed in each of the plurality of sub pixels. The plurality of banks BNK can be structures in which the plurality of micro LEDs (ED) is seated. The plurality of banks BNK can guide a position of the plurality of micro LEDs (ED) during a transfer process of transferring the plurality of micro LEDs (ED) to the display apparatus 1000. The plurality of micro LEDs (ED) can be transferred onto the plurality of banks BNK in the transfer process of the plurality of micro LEDs (ED). The plurality of banks BNK can be a bank pattern or a structure, but the example embodiments of the present disclosure are not limited thereto.

A bank BNK of the first sub pixel SP1, a bank BNK of the second sub pixel SP2, and a bank BNK of the third sub pixel SP3 can be disposed to be spaced apart from each other. The bank BNK of the first sub pixel SP1, the bank BNK of the second sub pixel SP2, and the bank BNK of the third sub pixel SP3 can be configured to be separated from each other. Therefore, the banks BNK of the first sub pixel SP1, the second sub pixel SP2, and the third sub pixel SP3 to which different types of micro LEDs (ED) are transferred can be easily identified.

The bank BNK of the 1-1-th sub pixel SP1a and the bank BNK of the 1-2-th sub pixel SP1b can be connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed can be connected to each other or spaced apart or separated from each other. The bank BNK of the 2-1-th sub pixel SP2a and the bank BNK of the 2-2-th sub pixel SP2b can be connected to each other, spaced apart or separated from each other. The bank BNK of the 3-1-th sub pixel SP3a and the bank BNK of the 3-2-th sub pixel SP3b can be connected to each other, spaced apart or separated from each other. Accordingly, the banks BNK of one pair of first sub pixels SP1, the banks BNK of one pair of second sub pixels SP2, and the banks BNK of third sub pixels SP3 can be formed in various forms, but the example embodiments of the present disclosure are not limited thereto.

For example, the plurality of banks BNK can be formed of an organic insulating material. The plurality of banks BNK can be configured by a single layer or a double layer of an organic insulating material. For example, the plurality of banks BNK can be configured by a photo resist, polyimide (PI), or acrylic material, but the example embodiments of the present disclosure are not limited thereto.

The first electrode CE1 can be disposed in each of the plurality of sub pixels. The first electrode CE1 can be disposed on the bank BNK. The first electrode CE1 can be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 can be electrically connected to the anode electrode 134 of the micro LED (ED) and transmit an anode voltage from the pixel driving circuit PD to the micro LED (ED) through the signal line TL. Different voltages can be applied to the first electrodes CE1 of the plurality of sub pixels depending on the image to be displayed. For example, different voltages can be applied to the first electrodes CE1 of the plurality of sub pixels. Therefore, the first electrode CE1 can be a pixel electrode, but the example embodiments of the present disclosure are not limited thereto.

The first electrode CE1 can be configured by a conductive material. For example, the first electrode CE1 can be integrally configured with the plurality of signal lines TL. For example, the first electrode CE1 can be configured by the same conductive material as the plurality of signal lines TL, but the example embodiments of the present disclosure are not limited thereto. For example, the first electrode CE1 can be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the first electrode CE1 can be configured by a multi-layered structure of conductive materials. For example, the plurality of first electrodes CE1 can be configured by a multi-layered structure of titanium (Ti)/aluminum (Al)/titanium (Ti)/indium tin oxide (ITO), but the example embodiments of the present disclosure are not limited thereto.

The micro LED (ED) can be disposed in each of the plurality of sub pixels. The plurality of micro LEDs (ED) can be any one of a light emitting diode or a micro light emitting diode (micro LED), but the example embodiments of the present disclosure are not limited thereto. The plurality of micro LEDs (ED) can be disposed on the bank BNK and the first electrode CE1. The plurality of micro LEDs (ED) can be disposed on the first electrode CE1 and can be electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) can include a first micro LED 130, a second micro LED 140, and a third micro LED 150. The first micro LED 130 can be disposed in the first sub pixel SP1. The second micro LED 140 can be disposed in the second sub pixel SP2. The third micro LED 150 can be disposed in the third sub pixel SP3. For example, any one of the first micro LED 130, the second micro LED 140, and the third micro LED 150 can be a red micro LED, another can be a green micro LED, and the third can be a blue micro LED, but the example embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the example embodiments of the present disclosure are not limited thereto.

The first micro LED 130 can include a 1-1-th micro LED 130a disposed in the 1-1-th sub pixel SP1a and a 1-2-th micro LED 130b disposed in the 1-2-th sub pixel SP1b. The second micro LED 140 can include a 2-1-th micro LED 140a disposed in the 2-1-th sub pixel SP2a and a 2-2-th micro LED 140b disposed in the 2-2-th sub pixel SP2b. The third micro LED 150 can include a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 can be disposed in each of the plurality of sub pixels. The second electrode CE2 can be disposed on the micro LED (ED). The second electrode CE2 can be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage can be applied to the second electrodes CE2 of the plurality of sub pixels. For example, the same voltage can be applied to the second electrode CE2 of each of the plurality of sub pixels and the cathode electrode 135 of the micro LED (ED). Therefore, the second electrode CE2 can be a common electrode, but the example embodiments of the present disclosure are not limited thereto.

At least some of the plurality of sub pixels can share the second electrode CE2. At least some of the second electrodes CE2 of the plurality of sub pixels can be electrically connected to each other. As the same voltage is applied to the second electrode CE2, the second electrodes CE2 of at least some of sub pixels are shared to be used. For example, the second electrodes CE2 of at least some pixels PX, among the plurality of pixels PX disposed on the same row, can be connected to each other. For example, one second electrode CE2 can be disposed in the plurality of pixels PX. One second electrode CE2 can be disposed in every n sub pixels.

For example, some of the second electrodes CE2 of the plurality of sub pixels can be disposed to be spaced apart or separated from each other. For example, a second electrode CE2 connected to pixels PX in an n-th row and a second electrode CE2 connected to pixels PX in an n+1-th row can be disposed to be spaced apart or separated from each other. For example, the plurality of second electrodes CE2 can be disposed to be spaced apart from each other with the plurality of communication lines NL extending in the row direction therebetween. Accordingly, the number of the plurality of sub pixels can be larger than the number of the plurality of second electrodes CE2. As another example, all the second electrodes CE2 of the plurality of sub pixels are connected to each other so that only one second electrode CE2 can be disposed on the substrate 110, but the example embodiments of the present disclosure are not limited thereto.

The plurality of second electrodes CE2 can be configured by a transparent conductive material, but the example embodiments of the present disclosure are not limited thereto. The plurality of second electrodes CE2 is configured by a transparent conductive material so that light emitted from the micro LED (ED) travels toward the top of the second electrode CE2. For example, the second electrode CE2 can be configured by a transparent conductive material, such as indium tin oxide (ITO), indium zinc oxide (IZO), indium gallium zinc oxide (IGZO), but the example embodiments of the present disclosure are not limited thereto.

A plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap a plurality of contact electrodes CCE.

For example, the plurality of contact electrodes CCE can be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

For example, when a micro LED is used as the micro LED (ED), a plurality of micro LEDs is formed on a wafer and the micro LED is transferred onto the substrate 110 of the display apparatus 1000 to manufacture the display apparatus 1000. However, during the process of transferring the plurality of micro LEDs (ED) having a micro size from the wafer to the substrate 110, various defects can be caused. For example, in some sub pixels, a non-transfer defect in which the micro LED is not transferred can occur and in the other sub pixels, a defect that the micro LED (ED) is transferred in a wrong position can occur due to the alignment error. Further, even though the transfer process is normally performed, the transferred micro LED (ED) can be defective. Accordingly, in consideration of the defects during the transfer process of the plurality of micro LEDs (ED), a plurality of same type micro LEDs can be transferred in one sub pixel. A lighting test for the plurality of micro LEDs (ED) is performed and only one micro LED (ED) which is finally determined to be normal can be used.

For example, the 1-1-th micro LED 130a and the 1-2-th micro LED 130b are transferred to one pixel PX together and defects thereof can be tested. If both the 1-1-th micro LED 130a and the 1-2-th micro LED 130b are determined to be normal, only the 1-1-th micro LED 130a can be used, but the 1-2-th micro LED 130b may not be used. As another example, if only the 1-2-th micro LED 130b between the 1-1-th micro LED 130a and the 1-2-th micro LED 130b is determined to be normal, the 1-1-th micro LED 130a may not be used, but only the 1-2-th micro LED 130b can be used. Accordingly, even though the plurality of same type micro LEDs (ED) is transferred to one pixel PX, finally, only one micro LED (ED) can be used.

Therefore, any one of one pair of micro LEDs (ED) can be a main (or primary) micro LED (ED) and the other micro LED (ED) can be a redundancy micro LED (ED). The redundancy micro LED (ED) can be an extra micro LED (ED) which is transferred to prepare for a defect of the main micro LED (ED). When the main micro LED (ED) is defective, the redundancy micro LED (ED) can be used instead. Accordingly, the main micro LED (ED) and the redundancy micro LED (ED) are transferred together to one pixel PX so that the degradation of the display quality due to the defects of the main micro LED (ED) and the redundancy micro LED (ED) can be minimized or reduced.

For example, a 1-1-th micro LED 130a, a 2-1-th micro LED 140a, and a 3-1-th micro LED 150a which are transferred into one pixel PX can be used as main micro LEDs (ED) and a 1-2-th micro LED 130b, a 2-2-th micro LED 140b, and a 3-2-th micro LED 150b can be used as redundancy micro LEDs (ED).

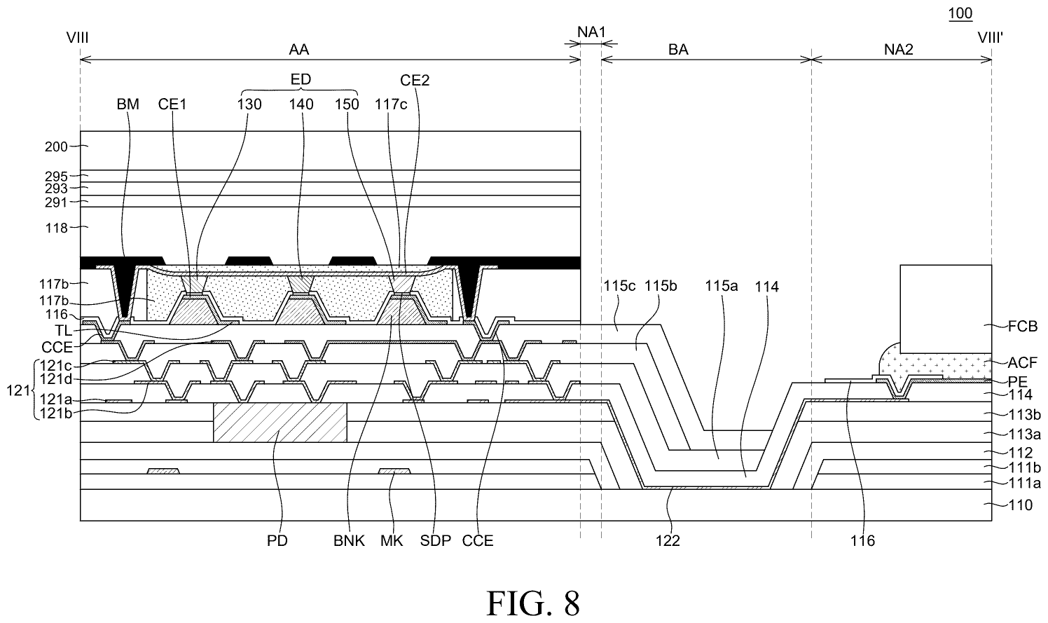

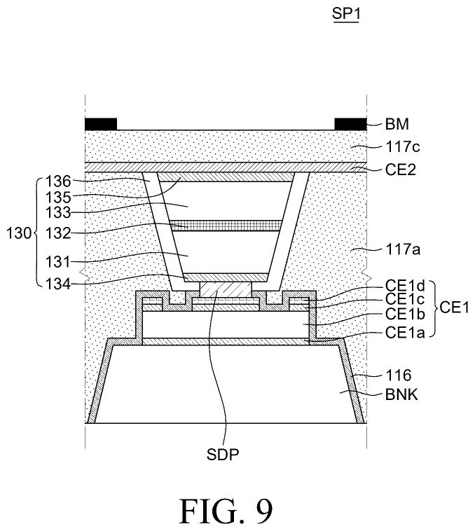

FIG. 8 is a cross-sectional view taken along VIII-VIII′ of FIG. 3. FIG. 9 is a cross-sectional view of a display apparatus according to an example embodiment of the present disclosure. FIG. 8 is a cross-sectional view of a display apparatus according to an example embodiment of the present disclosure. For example, FIG. 8 is a cross-sectional view of an active area AA, a first non-active area NA1, a bending area BA, and a second non-active area NA2. For example, FIG. 9 is an enlarged cross-sectional view of a first sub pixel. In the meantime, for the convenience of illustration, in FIG. 3, it is illustrated that a cross-sectional line of VIII-VIII′ and a driving line VL and a link line LL do not overlap, but the cross-sectional line VIII-VIII′ of FIG. 3 is provided to represent the same position as the adjacent driving line VL and link line LL.

Referring to FIG. 8, a first buffer layer 111a and a second buffer layer 111b can be disposed in the remaining area of the substrate 110 excluding the bending area BA.

The first buffer layer 111a and the second buffer layer 111b can be disposed in the active area AA, the first non-active area NA1, and the second non-active area NA2. The first buffer layer 111a and the second buffer layer 111b can reduce permeation of moisture or impurities through the substrate 110. The first buffer layer 111a and the second buffer layer 111b can be formed of an inorganic insulating material. For example, the first buffer layer 111a and the second buffer layer 111b can be configured by a single layer or multiple layers of silicon oxide (SiOx) or silicon nitride (SiNx), but the example embodiments of the present disclosure are not limited thereto.

For example, the first buffer layer 111a and the second buffer layer 111b on the bending area BA can be partially removed. A top surface of the substrate 110 located in the bending area BA can be exposed from the first buffer layer 111a and the second buffer layer 111b. The first buffer layer 111a and the second buffer layer 111b which are formed of an inorganic insulating material are removed from the bending area BA to minimize or reduce cracks of the first buffer layer 111a and the second buffer layer 111b which can be generated during the bending.

A plurality of alignment keys MK can be disposed between the first buffer layer 111a and the second buffer layer 111b. The plurality of alignment keys MK can be configured to identify a position of the pixel driving circuit PD during the manufacturing process of the display apparatus 1000. For example, the plurality of alignment keys MK can be configured to align a position of the pixel driving circuit PD which is transferred onto the adhesive layer 112. As another example, the plurality of alignment keys MK can be omitted.

The adhesive layer 112 can be disposed on the second buffer layer 111b. The adhesive layer 112 can be disposed in the active area AA, the first non-active area NA1, the bending area BA, and the second non-active area NA2.

For example, a part of the adhesive layer 112 disposed in the bending area BA can be removed. Therefore, a part of a top surface of the substrate 110 disposed in the bending area BA can be exposed from the adhesive layer 112, but it is not limited thereto and the adhesive layer 112 can be disposed in the active area AA and the entire non-active area NA including the bending area BA.

In the meantime, it is not limited thereto and the adhesive layer 112 can be continuously disposed in the active area AA, the first non-active area NA1, the bending area BA, and the second non-active area NA2 without being limited to that illustrated in the drawing.

For example, the adhesive layer 112 can be formed of any one of adhesive polymer, epoxy resin, UV curable resin, polyimide based, acrylate based, urethane based, and polydimethylsiloxane (PDMS), but the example embodiments of the present disclosure are not limited thereto.

The pixel driving circuit PD can be disposed on the adhesive layer 112 in the active area AA. When the pixel driving circuit PD is implemented as a driving driver, the driving driver can be mounted on the adhesive layer 112 by the transfer process, but the example embodiments of the present disclosure are not limited thereto.

A first protection layer 113a and a second protection layer 113b can be disposed on the adhesive layer 112 and the pixel driving circuit PD. For example, the first protection layer 113a and the second protection layer 113b can be disposed so as to enclose the side surface of the pixel driving circuit PD, but the example embodiments of the present disclosure are not limited thereto. For example, the second protection layer 113b can be disposed so as to cover at least a part of a top surface of the pixel driving circuit PD. For example, at least one of the first protection layer 113a and the second protection layer 113b disposed on the bending area BA can be omitted. For example, the first protection layer 113a can be entirely disposed in the active area AA and the non-active area NA and the second protection layer 113b can be partially disposed in the active area AA, the first non-active area NA1, and the second non-active area NA2. For example, a part of the second protection layer 113b in the bending area BA can be removed. However, the example embodiments of the present disclosure are not limited thereto and the first protection layer 113a and the second protection layer 113b may not be removed from the bending area BA in consideration of a neutral surface. For example, the first protection layer 113a and the second protection layer 113b can be continuously disposed in the active area AA, the first non-active area NA1, the bending area BA, and the second non-active area NA2, without being limited to that illustrated in the drawing.

For example, the first protection layer 113a and the second protection layer 113b disposed in the bending area BA can be partially removed. The first protection layer 113a and the second protection layer 113b which are formed of an organic insulating material are removed from the bending area BA to relieve the bending stress.

For example, the ends of the first protection layer 113a and the second protection layer 113b can be disposed in the bending area BA. For example, the first protection layer 113a can be disposed so as to enclose side surfaces of the first buffer layer 111a, the second buffer layer 111b, and the adhesive layer 112, but are not limited thereto.

The first protection layer 113a and the second protection layer 113b can be configured by an organic insulating material, but the example embodiments of the present disclosure are not limited thereto. For example, the first protection layer 113a and the second protection layer 113b can be configured by a photo resist, polyimide (PI), or photo acrylic material, but the example embodiments of the present disclosure are not limited thereto. For example, the first protection layer 113a and the second protection layer 113b can be over coating layers or insulating layers, but the example embodiments of the present disclosure are not limited thereto.

According to aspects of the present disclosure, in the active area AA, the plurality of first connection lines 121 can be disposed on the second protection layer 113b. The plurality of first connection lines 121 can be wiring lines which electrically connect the pixel driving circuit PD to the other component. For example, the pixel driving circuit PD can be electrically connected to the plurality of signal lines TL and the plurality of contact electrodes CCE through the plurality of first connection lines 121. For example, the plurality of first connection lines 121 can include a 1-1-th connection line 121a, a 1-2-th connection line 121b, a 1-3-th connection line 121c, and a 1-4-th connection line 121b, but the example embodiments of the present disclosure are not limited thereto.

For example, the plurality of 1-1-th connection lines 121a can be disposed on the second protection layer 113b. The plurality of 1-1-th connection lines 121a can be electrically connected to the pixel driving circuit PD. The plurality of 1-1-th connection lines 121a can transmit a voltage output from the pixel driving circuit PD to the first electrode CE1 or the second electrode CE2.

For example, a third protection layer 114 can be disposed on the second protection layer 113b. The third protection layer 114 can be entirely disposed in the active area AA and the non-active area NA. In the bending area BA, the third protection layer 114 can cover side surfaces of the second protection layer 113b and the first protection layer 113a. The third protection layer 114 can be configured by an organic insulating material. For example, the third protection layer 114 can be configured by a photo resist, polyimide (PI), or photo acrylic material, but the example embodiments of the present disclosure are not limited thereto. For example, the first protection layer 113a, the second protection layer 113b, and the third protection layer 114 can be configured by the same material, but the example embodiments of the present disclosure are not limited thereto.

The plurality of 1-2-th connection lines 121b can be disposed on the third protection layer 114. The plurality of 1-2-th connection lines 121b can be indirectly or directly connected to the pixel driving circuit PD. For example, a part of the 1-2-th connection line 121b can be directly connected to the pixel driving circuit PD through a contact hole of the third protection layer 114. The other part of the 1-2-th connection line 121b can be electrically connected to the 1-1-th connection line 121a through the contact hole of the third protection layer 114, but the example embodiments of the present disclosure are not limited thereto. A voltage output from the pixel driving circuit PD can be transmitted to the first electrode CE1 or the second electrode CE2 through a connection line other than the plurality of 1-2-th connection lines 121b.

The first insulating layer 115a can be disposed on the plurality of 1-2-th connection lines 121b. The first insulating layer 115a can be disposed in the active area AA, the first non-active area NA1, and the bending area BA. For example, the first insulating layer 115a can be disposed in an area excluding the second non-active area NA2, but the example embodiments of the present disclosure are not limited thereto.

For example, a part of the first insulating layer 115a disposed in the second non-active area NA2 can be removed. The first insulating layer 115a which is formed of an organic insulating material is removed from the second non-active area NA2 so that a pressure which is additionally applied to the second connection line 122 by the first insulating layer 115a when the plurality of pad electrodes PE and the flexible circuit board FCB are bonded can be minimized or reduced.

Therefore, an end of the first insulating layer 115a can be disposed in the bending area BA. At this time, in the bending area BA, the end of the first insulating layer 115a can be in contact with a side surface of the third protection layer 114, but it is not limited thereto.

The first insulating layer 115a can be configured by an organic insulating material, but the example embodiments of the present disclosure are not limited thereto. For example, the first insulating layer 115a can be configured by a photo resist, polyimide (PI), or photo acrylic material, but the example embodiments of the present disclosure are not limited thereto.

The plurality of 1-3-th connection lines 121c can be disposed on the first insulating layer 115a. The plurality of 1-3-th connection lines 121c can be electrically connected to the plurality of 1-2-th connection lines 121b. For example, the 1-3-th connection lines 121c can be electrically connected to the 1-2-th connection line 121b through a contact hole of the first insulating layer 115a.

The second insulating layer 115b can be disposed on the plurality of 1-3-th connection lines 121c. The second insulating layer 115b can be disposed in an area other than the second non-active area NA2, similar to the first insulating layer 115a. For example, the second insulating layer 115b can be disposed in the active area AA, the first non-active area NA1, and the bending area BA, but the example embodiments of the present disclosure are not limited thereto.

For example, a part of the second insulating layer 115b disposed in the second non-active area NA2 can be removed. The second insulating layer 115b which is formed of an organic insulating material is removed from the second non-active area NA2 so that a pressure which is additionally applied to the second connection line 122 by the second insulating layer 115b when the plurality of pad electrodes PE and the flexible circuit board FCB are bonded can be minimized or reduced.

Therefore, an end of the second insulating layer 115b can be disposed in the bending area BA. For example, the end of the second insulating layer 115b can be disposed between the first insulating layer 115a and the third insulating layer 115c, but it is not limited thereto. Therefore, the end of the second insulating layer 115b extends to be in contact with the third protection layer 114, similar to the first insulating layer 115a and the third insulating layer 115c.

For example, the second insulating layer 115b can be configured by an organic insulating material, but the example embodiments of the present disclosure are not limited thereto. For example, the second insulating layer 115b can be configured by a photo resist, polyimide (PI), or photo acrylic material, but the example embodiments of the present disclosure are not limited thereto.

The plurality of 1-4-th connection lines 121d can be disposed on the second insulating layer 115b. The plurality of 1-4-th connection lines 121d can be electrically connected to the plurality of 1-3-th connection lines 121c. For example, the 1-4-th connection lines 121d can be electrically connected to the 1-3-th connection line 121c through a contact hole of the second insulating layer 115b.

According to aspects of the present disclosure, in the non-active area NA, the plurality of second connection lines 122 can be disposed. For example, the plurality of second connection lines 122 can be disposed on different layers in the first non-active area NA1, the bending area BA, and the second non-active area NA2 of the non-active area NA. For example, the plurality of second connection lines 122 can be disposed on the second protection layer 113b in the first non-active area NA1 and the second non-active area NA2. Further, in the bending area BA, a partial layer including the second protection layer 113b is removed so that the plurality of second connection lines can be disposed on the substrate 110, but it is not limited thereto.

For example, in at least a part of the non-active area NA, the plurality of second connection lines 122 can be disposed on the second protection layer 113b. For example, some of the plurality of second connection lines 122 which is disposed in the first non-active area NA1 and the second non-active area NA2 can be disposed on the same layer as the 1-1-th connection line 121a, among the plurality of first connection lines 121, but it is not limited thereto. The plurality of second connection lines 122 can be wiring lines which transmit a signal transmitted from the flexible circuit board (or flexible film) FCB and the printed circuit board 160 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) FCB and the printed circuit board.

For example, the plurality of second connection lines 122 extends toward the active area AA from the pad unit PAD to transmit a signal to the wiring line of the active area AA. In this case, the plurality of second connection lines 122 can serve as a link line LL.

In the second non-active area NA2, the plurality of second connection lines 122 can be disposed on the second protection layer 113b. The plurality of second connection lines 122 can extend from the second non-active area NA2 to the bending area BA and the first non-active area NA1. The plurality of second connection lines 122 can transmit a signal transmitted from the flexible circuit board (or flexible film) FCB and the printed circuit board 160 to the pad unit PAD to the pixel driving circuit PD of the active area AA.

In the meantime, some of the first buffer layer 111a, the second buffer layer 111b, the adhesive layer 112, the first protection layer 113a, and the second protection layer 113b are removed from the bending area BA. Therefore, the plurality of second connection lines 122 is disposed on the substrate 110 in the bending area BA to be in contact with the substrate 110, but is not limited thereto.

The plurality of first connection lines 121 and the plurality of second connection lines 122 can be formed of any one of a conductive material having excellent ductility or various conductive materials used for the active area AA. For example, the second connection line 122 which is partially disposed in the bending area BA can be configured by a conductive material having excellent ductility, such as gold (Au), silver (Ag), or aluminum (Al), but the example embodiments of the present disclosure are not limited thereto. As another example, the plurality of first connection lines 121 and the plurality of second connection lines 122 can be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto.

The third insulating layer 115c can be disposed on the plurality of first connection lines 121. The third insulating layer 115c can be disposed in an area other than the second non-active area NA2, similar to the first insulating layer 115a and the second insulating layer 115b. For example, the third insulating layer 115c can be disposed in the active area AA, the first non-active area NA1, and the bending area BA, and a part of the third insulating layer 115c in the second non-active area NA2 can be removed, but the example embodiments of the present disclosure are not limited thereto.

For example, a part of the third insulating layer 115c disposed in the second non-active area NA2 can be removed. The third insulating layer 115c which is formed of an organic insulating material is removed from the second non-active area NA2 so that a pressure which is additionally applied to the second connection line 122 by the third insulating layer 115c when the plurality of pad electrodes PE and the flexible circuit board FCB are bonded can be minimized or reduced.

Therefore, an end of the third insulating layer 115c can be disposed in the bending area BA. Further, in the bending area BA, the end of the third insulating layer 115c can be in contact with a side surface of the third protection layer 114, but it is not limited thereto.

The third insulating layer 115c can be configured by an organic insulating material, but the example embodiments of the present disclosure are not limited thereto. For example, the third insulating layer 115c can be configured by a photo resist, polyimide (PI), or photo acrylic material, but the example embodiments of the present disclosure are not limited thereto.

A plurality of banks BNK can be disposed on the third insulating layer 115c in the active area AA. The plurality of banks BNK can be disposed so as to overlap each of the plurality of sub pixels. One or more same type micro LEDs (ED) can be disposed above each of the plurality of banks BNK.

A plurality of signal lines TL can be disposed on the third insulating layer 115c in the active area AA. The plurality of signal lines TL can be disposed in an area between the plurality of banks BNK. For example, the plurality of signal lines TL can be disposed to be adjacent to any one of the plurality of banks BNK.

A plurality of contact electrodes CCE can be disposed on the third insulating layer 115c in the active area AA. The plurality of contact electrodes CCE can supply a cathode voltage from the pixel driving circuit PD to the second electrode CE2.

The first electrode CE1 can be disposed on the bank BNK. For example, the first electrode CE1 can be disposed to extend toward the top of the bank BNK from the adjacent signal line TL. The first electrode CE1 can be disposed on the top surface of the bank BNK and the side surface of the bank BNK. For example, the first electrode CE1 can be disposed to extend from the signal line TL on the top surface of the third insulating layer 115c to the side surface of the bank BNK and the top surface of the bank BNK.

Referring to FIG. 9, the first electrode CE1 can be configured by a plurality of conductive layers. For example, the first electrode CE1 can include a first conductive layer CE1a, a second conductive layer CE1b, a third conductive layer CE1c, and a fourth conductive layer CE1d, but the example embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, the first conductive layer CE1a, the second conductive layer CE1b, the third conductive layer CE1c, and the fourth conductive layer CE1d can be configured by titanium (Ti), molybdenum (Mo), aluminum (Al), or titanium (Ti) and indium tin oxide (ITO), but the example embodiments of the present disclosure are not limited thereto.

According to aspects of the present disclosure, some conductive layers having a good reflection efficiency, among a plurality of conductive layers which configures the first electrode CE1, can be configured as an alignment key for alignment of the micro LED (ED) and/or a reflective plate. For example, the second conductive layer CE1b, among the plurality of conductive layers of the first electrode CE1, can include a reflective material. For example, the second conductive layer CE1b can include aluminum (Al), but the example embodiments of the present disclosure are not limited thereto. Therefore, the second conductive layer CE1b can be configured as a reflective plate. Further, the second conductive layer CE1b has a high reflection efficiency to be easily identified during the manufacturing process so that a position of the micro LED (ED) or a transfer position can be aligned based on the second conductive layer CE1b.

For example, in order to the second conductive layer CE1b as a reflective plate, the third conductive layer CE1c and the fourth conductive layer CE1d which cover the second conductive layer CE1b can be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed can remain and the remaining portion excluding the portions can be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 can be suppressed.

According to aspects of the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which is adhesive to the solder pattern SPD, and has anti-corrosion and acid resistance, but the example embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the example embodiments of the present disclosure are not limited thereto.

According to aspects of the present disclosure, the signal line TL, the contact electrode CCE, and the pad electrode PE disposed on the same layer as the first electrode CE1 can be configured by multiple layers of conductive materials, but the example embodiments of the present disclosure are not limited thereto. For example, the signal line TL, the contact electrode CCE, and the pad electrode PE can be formed of multiple layers of indium tin oxide (ITO)/titanium (Ti)/aluminum (Al)/titanium (Ti), but the example embodiments of the present disclosure are not limited thereto.

According to aspects of the present disclosure, in each of the plurality of sub pixels, a solder pattern SDP can be disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) can be electrically connected through eutectic bonding using the solder pattern SDP, but the example embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) can be bonded to the solder pattern SDP and the first electrode CE1 using the eutectic bonding without a separate adhesive material. For example, the solder pattern SDP can be configured by indium (Id), tin (Sn), or an alloy thereof, but the example embodiments of the present disclosure are not limited thereto. For example, the solder pattern SDP can be a bonding pad or an adhesive pad, but the example embodiments of the present disclosure are not limited thereto.

According to aspects of the present disclosure, the passivation layer 116 can be disposed on the plurality of signal lines TL, the plurality of first electrodes CE1, the plurality of contact electrodes CCE, the third insulating layer 115c, and the third protection layer 114. For example, the passivation layer 116 can be disposed in the active area AA, the first non-active area NA1, and the second non-active area NA2. A part of the passivation layer 116 disposed in the bending area BA can be removed. A part of the passivation layer 116 which covers a plurality of pad electrodes PE in the second non-active area NA2 can be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 can be configured by a single layer or multiple layers of silicon oxide (SiOx) or silicon nitride (SiNx), but the example embodiments of the present disclosure are not limited thereto. For example, the passivation layer 116 can be a protection layer or an insulating layer, but the example embodiments of the present disclosure are not limited thereto. For example, the passivation layer 116 can include a hole through which the solder pattern SDP is exposed.

In each of the plurality of sub pixels, the micro LED (ED) can be disposed on the solder pattern SDP. A first micro LED 130 can be disposed in the first sub pixel SP1. A second micro LED 140 can be disposed in the second sub pixel SP2. A third micro LED 150 can be disposed in the third sub pixel SP3.

The micro LED (ED) can be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the example embodiments of the present disclosure are not limited thereto.

Referring to FIG. 9, the first micro LED 130 can include an anode electrode 134, a first semiconductor layer 131, an active layer 132, a second semiconductor layer 133, a cathode electrode 135, and an encapsulation film 136, but the example embodiments of the present disclosure are not limited thereto. For example, the encapsulation film 136 may not be included in the first micro LED 130.

The first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented by a compound semiconductor, such as a III-V group or a II-VI group and can be doped with an impurity (or dopant). For example, one of the first semiconductor layer 131 and the second semiconductor layer 133 can be an n-type impurity-doped semiconductor layer and the other one can be a p-type impurity-doped semiconductor, but the example embodiments of the present disclosure are not limited thereto. For example, one or more of the first semiconductor layer 131 and the second semiconductor layer 133 can be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto. For example, the n-type impurity can be silicon (Si), germanium (Ge), selenium (Se), carbon (C), tellurium (Te), or tin (Sn), but the example embodiments of the present disclosure are not limited thereto. For example, the p-type impurity can be magnesium (Mg), zinc (Zn), calcium (Ca), strontium (Sr), barium (Ba), or beryllium (Be), but the example embodiments of the present disclosure are not limited thereto.

For example, each the first semiconductor layer 131 and the second semiconductor layer 133 can be a nitride semiconductor including an n-type impurity or a nitride semiconductor including a p-type impurity, but the example embodiments of the present disclosure are not limited thereto. For example, the first semiconductor layer 131 can be a nitride semiconductor including a p-type impurity and the second semiconductor layer 133 can be a nitride semiconductor including an n-type impurity, but the example embodiments of the present disclosure are not limited thereto.

The active layer 132 can be disposed between the first semiconductor layer 131 and the second semiconductor layer 133. The active layer 132 is supplied with holes and electrons from the first semiconductor layer 131 and the second semiconductor layer 133 to emit light. For example, the active layer 132 can be configured by one of a single well structure, a multi-well structure, a signal quantum well structure, a multi-quantum well (MQC) structure, a quantum dot structure, and a quantum line structure, but the example embodiments of the present disclosure are not limited thereto. For example, the active layer 132 can be configured by indium gallium nitride (InGaN) or gallium nitride (GaN), but the example embodiments of the present disclosure are not limited thereto.

As another example, the active layer 132 can have a multi quantum well (MQW) structure having a well layer and a barrier layer with a band gap higher than the well layer. For example, in the active layer 132, InGaN can be configured as a well layer and an AlGaN layer can be configured as a barrier layer, but the example embodiments of the present disclosure are not limited thereto.

The anode electrode 134 can be disposed between the first semiconductor layer 131 and the solder pattern SDP. For example, the anode electrode 134 can electrically connect the first semiconductor layer 131 and the first electrode CE1. The anode voltage output from the pixel driving circuit PD can be applied to the first semiconductor layer 131 through the signal line TL, the first electrode CE1, and the anode electrode 134. For example, the anode electrode 134 can be configured by a conductive material which can form eutectic bonding with the solder pattern SDP, but the example embodiments of the present disclosure are not limited thereto. For example, the anode electrode 134 can be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example embodiments of the present disclosure are not limited thereto.

The cathode electrode 135 can be disposed on the second semiconductor layer 133. For example, the cathode electrode 135 can electrically connect the second semiconductor layer 133 and the second electrode CE2. A cathode voltage output from the pixel driving circuit PD can be applied to the second semiconductor layer 133 through the contact electrode CCE, the second electrode CE2, and the cathode electrode 135. The cathode electrode 135 can be configured by a transparent conductive material to allow light emitted from the micro LED (ED) to be directed to the top of the micro LED (ED), but the example embodiments of the present disclosure are not limited thereto. For example, the cathode electrode 135 can be configured by a material, such as indium tin oxide (ITO), indium zinc oxide (IZO), indium gallium zinc oxide (IGZO), but the example embodiments of the present disclosure are not limited thereto.

The encapsulation film 136 can be disposed in at least a part of the first semiconductor layer 131, the active layer 132, the second semiconductor layer 133, the anode electrode 134, and the cathode electrode 135. For example, the encapsulation film 136 can enclose at least a part of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133.

For example, the encapsulation film 136 can be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP can be connected. For example, at least a part of the cathode electrode 135 is exposed from the encapsulation film 136 so that the cathode electrode 135 and the second electrode CE2 can be connected. For example, the encapsulation film 136 can be formed of an insulating material, such as silicon nitride (SiNx) or silicon oxide (SiOx), but the example embodiments of the present disclosure are not limited thereto.

As another example, the encapsulation film 136 can have a structure in which a reflective material is dispersed in a resin layer, but the example embodiments of the present disclosure are not limited thereto. For example, the encapsulation film 136 can be manufactured with reflectors with various structures, but the example embodiments of the present disclosure are not limited thereto. Light emitted from the active layer 132 is upwardly reflected by the encapsulation film 136 so that light extraction efficiency can be improved. For example, the encapsulation film 136 can be a reflective layer, but the example embodiments of the present disclosure are not limited thereto.

According to aspects of the present disclosure, it is described that the micro LED (ED) has a vertical structure, but the example embodiments of the present disclosure are not limited thereto. For example, the micro LED (ED) can have a lateral structure or a flip-chip structure.

The first micro LED 130 has been described with reference to FIG. 9 and the second micro LED 140 and the third micro LED 150 can have substantially the same structure as the first micro LED 130. For example, the second micro LED 140 and the third micro LED 150 can be substantially the same as the first semiconductor layer 131, the active layer 132, the second semiconductor layer 133, the anode electrode 134, the cathode electrode 135, and the encapsulation film 136 of the first micro LED 130.

According to aspects of the present disclosure, in the active area AA, a first optical layer 117a which encloses the plurality of micro LEDs (ED) can be disposed. For example, the first optical layer 117a can be disposed so as to cover the plurality of micro LEDs (ED) and the bank BNK in the area of the plurality of sub pixels. For example, the first optical layer 117a can cover the bank BNK, a part of the passivation layer 116 and between the plurality of micro LEDs (ED). The first optical layer 117a can be disposed or cover between the plurality of micro LEDs (ED) and between the plurality of banks BNK included in one pixel PX. For example, the first optical layer 117a extends in a first row direction and can be disposed to be spaced apart from each other in a second column direction. For example, the first optical layer 117a can be disposed so as to enclose side portions of the micro LED (ED) and the bank BNK between the passivation layer 116 and the second electrode CE2, but the example embodiments of the present disclosure are not limited thereto. For example, the first optical layer 117a can be a diffusion layer or a side wall diffusion layer, but the example embodiments of the present disclosure are not limited thereto.

The first optical layer 117a can include an organic insulating material in which micro particles are dispersed, but the example embodiments of the present disclosure are not limited thereto. For example, the first optical layer 117a can be configured by siloxane in which micro metal particles, such as titanium dioxide (TiO₂) particles, are dispersed, but the example embodiments of the present disclosure are not limited thereto. Light from the plurality of micro LEDs (ED) is scattered by micro particles dispersed in the first optical layer 117a to be emitted to the outside of the display apparatus 1000. Accordingly, the first optical layer 117a can improve extraction efficiency of light emitted from the plurality of micro LEDs (ED).

For example, the first optical layer 117a can be disposed in each of the plurality of pixels PX or disposed in some pixels PX disposed in the same row together, but the example embodiments of the present disclosure are not limited thereto. For example, the first optical layer 117a can be disposed in each of the plurality of pixels PX or the plurality of pixels PX can share one first optical layer 117a. As another example, each of the plurality of sub pixels can separately include the first optical layer 117a, but the example embodiments of the present disclosure are not limited thereto.

According to aspects of the present disclosure, in the active area AA, a second optical layer 117b can be disposed on the passivation layer 116. For example, the second optical layer 117b can be disposed so as to enclose the first optical layer 117a. For example, the second optical layer 117b can be in contact with a side surface of the first optical layer 117a. For example, the second optical layer 117b can be disposed in an area between the plurality of pixels PX. However, the example embodiments of the present disclosure are not limited thereto. For example, the second optical layer 117b can be a diffusion layer, a diffusion window, or a window diffusion layer, but the example embodiments of the present disclosure are not limited thereto.

The second optical layer 117b can be configured by an organic insulating material, but the example embodiments of the present disclosure are not limited thereto. The second optical layer 117b can be configured by the same material as the first optical layer 117a, but the example embodiments of the present disclosure are not limited thereto. For example, the first optical layer 117a can include micro particles, but the second optical layer 117b may not include micro particles. For example, the second optical layer 117b can be configured by siloxane, but the example embodiments of the present disclosure are not limited thereto.

For example, a thickness of the first optical layer 117a can be smaller than a thickness of the second optical layer 117b, but the example embodiments of the present disclosure are not limited thereto. Accordingly, in the plan view, an area in which the first optical layer 117a is disposed can include a concave portion which is inwardly dented from an upper surface of the second optical layer 117b.

According to aspects of the present disclosure, the second electrode CE2 can be disposed on the first optical layer 117a and the second optical layer 117b. For example, the second electrode CE2 can be electrically connected to the plurality of contact electrodes CCE through a contact hole of the second optical layer 117b. For example, the second electrode CE2 can be disposed on the plurality of micro LEDs (ED). For example, the second electrode CE2 can include a transparent conductive oxide, such as indium tin oxide (ITO) or indium zinc oxide (IZO), but the example embodiments of the present disclosure are not limited thereto. For example, the second electrode CE2 can be disposed to be in contact with the cathode electrode 135. For example, the second electrode CE2 can overlap the first optical layer 117a. For example, the second electrode can cover a plane at the outside of the first optical layer 117a.

The second electrode CE2 can continuously extend in a first direction of the substrate 110. Accordingly, the second electrode can be commonly connected to the plurality of pixels PX disposed in the first direction of the substrate 110. For example, the second electrode CE2 can be commonly connected to the plurality of pixels PX.

According to aspects of the present disclosure, the second electrode CE2 can continuously extend on the first optical layer 117a, the second optical layer 117b, and the micro LED (ED). The area in which the first optical layer 117a is disposed can include a concave portion which is inwardly dented from an upper surface of the second optical layer 117b. Accordingly, the first part of the second electrode CE2 disposed on the first optical layer 117a is disposed along the concave portion so that the first part can be disposed to be lower than the second part of the second electrode CE2 disposed on the second optical layer 117b.

The third optical layer 117c can be disposed on the second electrode CE2. The third optical layer 117c can be disposed so as to overlap the plurality of micro LEDs (ED) and the first optical layer 117a. The third optical layer 117c is disposed above the second electrode CE2 and the plurality of micro LEDs (ED) so that mura which can be generated in a part of the plurality of micro LEDs (ED) can be improved. For example, when the plurality of micro LEDs (ED) is transferred onto the substrate 110 of the display apparatus 1000, an area in which the interval between the plurality of micro LEDs (ED) is not uniform can be caused due to a process deviation. When the interval between the plurality of micro LEDs (ED) is not uniform, an emission area of each of the plurality of micro LEDs (ED) is not uniformly disposed so that the mura can be visible to a user. Accordingly, the third optical layer 117c which is configured to uniformly diffuse light is configured above the plurality of micro LEDs (ED) so that light emitted from some micro LEDs (ED) which is visible as mura can be reduced. Accordingly, light emitted from the plurality of micro LEDs (ED) is uniformly diffused by the third optical layer 117c to be extracted to the outside of the display apparatus 1000 so that the luminance uniformity of the display apparatus 1000 can be improved.

The third optical layer 117c can be configured by an organic insulating material in which micro particles are dispersed, but the example embodiments of the present disclosure are not limited thereto. For example, the third optical layer 117c can be configured by siloxane in which micro metal particles, such as titanium dioxide (TiO₂) particles, are dispersed, but the example embodiments of the present disclosure are not limited thereto. For example, the third optical layer 117c can be configured by the same material as the first optical layer 117a, but the example embodiments of the present disclosure are not limited thereto. For example, the third optical layer 117c can be a diffusion layer or an upward diffusion layer, but the example embodiments of the present disclosure are not limited thereto.

According to aspects of the present disclosure, light from the plurality of micro LEDs (ED) is scattered by micro particles dispersed in the third optical layer 117c to be emitted to the outside of the display apparatus 1000. The third optical layer 117c uniformly mixes light emitted from the plurality of micro LEDs (ED) to further improve the luminance uniformity of the display apparatus 1000. The light extraction efficiency of the display apparatus 1000 can be improved by light scattered from the plurality of micro particles so that the display apparatus 1000 can be driven at a low power.

In the active area AA, a black matrix BM can be disposed on the second electrode CE2, the first optical layer 117a, the second optical layer 117b, and the third optical layer 117c. For example, the contact hole of the second optical layer 117b can be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels can be suppressed.

For example, the black matrix BM can be configured by an opaque material, but the example embodiments of the present disclosure are not limited thereto. For example, the black matrix BM can be configured by an organic insulating material to which black pigment or black dye is added, but the example embodiments of the present disclosure are not limited thereto.

In the active area AA, a cover layer 118 can be disposed on the black matrix BM. The cover layer 118 can protect configurations below the cover layer 118. For example, the cover layer 118 can be configured by an organic insulating material, but the example embodiments of the present disclosure are not limited thereto. For example, the cover layer 118 can be configured by a photo resist, polyimide (PI), or photo acrylic material, but the example embodiments of the present disclosure are not limited thereto. For example, the cover layer 118 can be an over coating layer or an insulating layer, but the example embodiments of the present disclosure are not limited thereto.

A polarization layer 293 can be disposed on the cover layer 118 by means of the first adhesive layer 291. A cover member 120 can be disposed on the polarization layer 293 by means of the second adhesive layer 295. For example, the first adhesive layer 291 and the second adhesive layer 295 can include an optically clear adhesive (OCA), an optically clear resin (OCR), or a pressure sensitive adhesive (PSA), but the example embodiments of the present disclosure are not limited thereto.

According to aspects of the present disclosure, a plurality of pad electrodes PE can be disposed on the third protection layer 114 in the second non-active area NA2. For example, the plurality of pad electrodes PE can be disposed on the same layer as the 1-2-th connection line 121b, among the plurality of first connection lines 121, but is not limited thereto. For example, at least some of the plurality of pad electrodes PE can be exposed from the passivation layer 116.

For example, the plurality of pad electrodes PE can be directly and electrically connected to the plurality of second connection lines 122 through a contact hole of the third protection layer 114.

The first insulating layer 115a, the second insulting layer 115b, and the third insulating layer 115c are partially removed from the second non-active area NA2 so that only the third protection layer 114 can be disposed between the plurality of pad electrodes PE and the plurality of second connection lines 122, but is not limited thereto.

Therefore, a height of the plurality of pad electrodes PE can be lower than the 1-3-th connection line 121c disposed on the first insulating layer 115a and the 1-4-th connection line 121d disposed on the second insulating layer 115b, but is not limited thereto.

The adhesive layer ACF can be disposed on the plurality of pad electrodes PE. The adhesive layer ACF can be an adhesive layer in which conductive balls are dispersed in an insulating material, but the example embodiments of the present disclosure are not limited thereto. When heat or pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) FCB, the flexible circuit board (or flexible film) FCB can be attached or bonded to the plurality of pad electrodes PE. For example, the adhesive layer ACF can be anisotropic conductive film, but the example embodiments of the present disclosure are not limited thereto.

The flexible circuit board (or flexible film) FCB can be disposed on the adhesive layer ACF. The flexible circuit board (or flexible film) FCB can be electrically connected to the plurality of pad electrodes PE through the adhesive layer ACF. Accordingly, a signal output from the flexible circuit board (or flexible film) FCB and the printed circuit board 160 can be transmitted to the pixel driving circuit PD of the active area AA through the plurality of pad electrodes PE and the second connection line 122.

In order to transmit a signal which is transmitted from the flexible circuit board to the plurality of pad electrodes to the pixel driving circuit of the active area, a plurality of connection lines can be disposed in the non-active area. For example, the plurality of connection lines is disposed on the plurality of organic insulating layers to be connected to the plurality of pad electrodes with the plurality of organic insulating layers therebetween.

In the meantime, a conductive adhesive layer is disposed between the plurality of pad electrodes and the flexible circuit board to apply heat or pressure to attach or bond the flexible circuit board to the plurality of pad electrodes. Therefore, the pressure which is applied during the bonding can also be transmitted to the plurality of connection lines disposed below the plurality of pad electrodes as it is.

At this time, not only the pressure applied during the bonding, but also a pressure by the plurality of organic insulating layers can also be added to a connection line which is disposed lower than the others, among the plurality of connection lines. For example, a connection line which is disposed lower than the others can be more vulnerable to the pressure. Therefore, when the plurality of pad electrodes and the flexible circuit boards are bonded, the plurality of connection lines can be lifted due to the pressure and the moisture or oxygen permeates between a lifted space to degrade the reliability. Accordingly, there is a problem in that when the plurality of pad electrodes and the flexible circuit board are bonded, a pressure is restrictively applied in consideration thereof.

Therefore, in the display apparatus 1000 according to the example embodiment of the present disclosure, only a minimum organic insulating layer can be disposed between the plurality of pad electrodes PE and the plurality of second connection lines 122. For example, the first insulating layer 115a, the second insulating layer 115b, and the third insulating layer 115c which are formed of an organic insulating material can be disposed excluding the second non-active area NA2 in which the plurality of pad electrodes PE is disposed. For example, the first insulating layer 115a, the second insulating layer 115b, and the third insulating layer 115c which are disposed between the plurality of second connection lines 122 and the plurality of pad electrodes PE can be removed. Therefore, a minimum organic insulating layer, for example, only the third protection layer 114 can be disposed between the plurality of second connection lines 122 and the plurality of pad electrodes PE. Accordingly, in addition to a pressure applied while bonding the flexible circuit board FCB and the plurality of pad electrodes PE, a pressure applied to the plurality of second connection lines 122 by the first insulating layer 115a, the second insulating layer 115b, and the third insulating layer 115c can be minimized or reduced. Therefore, a pressure margin for bonding the flexible circuit board FCB and the plurality of pad electrodes PE can be ensured while minimizing or reducing the lifting of the plurality of second connection lines 122.

Accordingly, in the display apparatus 1000 according to the example embodiment of the present disclosure, the lifting of the plurality of second connection lines 122 is minimized or reduced to suppress bubbles and permeation of moisture or oxygen through the lifted space can be minimized or reduced. Therefore, the reliability of the display apparatus 1000 can be improved. Further, a stronger pressure is applied to bond the flexible circuit board FCB and the plurality of pad electrodes PE by ensuring a pressure margin for bonding the flexible circuit board FCB and the plurality of pad electrodes PE. Therefore, the electrical connection between the plurality of pad electrodes PE and the flexible circuit board FCB can be improved.

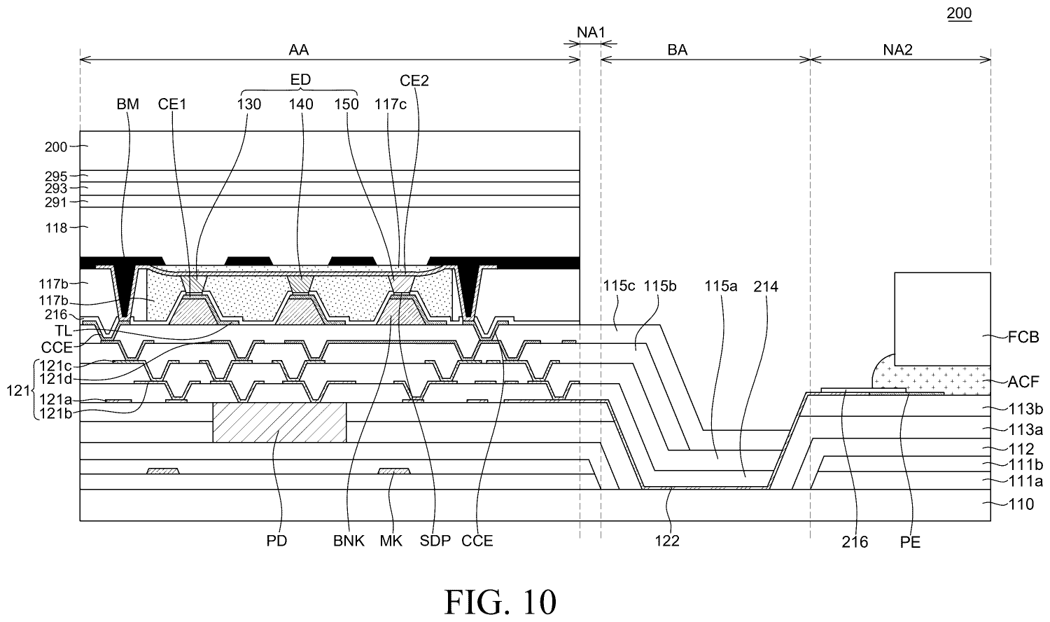

FIG. 10 is a cross-sectional view of a display apparatus according to another example embodiment of the present disclosure. FIG. 10 is a cross-sectional view of the same area as in FIG. 8. One or only difference between a display apparatus of FIG. 10 and the display apparatus of FIGS. 1 to 9 is a placement area of a third protection layer 214, a plurality of pad electrodes PE, and a passivation layer 216 of a display panel 200 and the other component is substantially the same so that a redundant description will be omitted.

Referring to FIG. 10, the third protection layer 214 can be disposed in an area excluding the second non-active area NA2. For example, the third protection layer 214 can be disposed in only the active area AA, the first non-active area NA1, and the bending area BA. The third protection layer 214 which is formed of an organic insulating material is removed from the second non-active area NA2. Therefore, a pressure which is additionally applied to the second connection line 122 by the third protection layer 214, other than a pressure which is applied to the second connection line 122 when the plurality of pad electrodes PE and the flexible circuit board FCB are bonded, can be minimized or reduced.

Therefore, an end of the third protection layer 214 can be disposed in the bending area BA. At this time, the end of the third protection layer 214 can be in contact with side surfaces of the plurality of second connection lines 122 in the bending area BA, but is not limited thereto.

In the meantime, not only the first insulating layer 115a, the second insulating layer 115b, and the third insulating layer 115c disposed between the plurality of pad electrodes PE and the plurality of second connection lines 122, but also the third protection layer 214 is removed. Therefore, the plurality of pad electrodes PE can be disposed on the second protection layer 113b. For example, the plurality of pad electrodes PE and the plurality of second connection lines 122 are disposed on the same layer to be directly connected. For example, side surfaces of the plurality of second connection lines 122 and side surfaces of the plurality of pad electrodes PE are in contact with each other to be connected, but are not limited thereto.

In the meantime, the plurality of pad electrodes PE is disposed on the second protection layer 113b, to be disposed on the same layer as the 1-1-th connection line 121a disposed on the second protection layer 113b in the active area AA, but is not limited thereto.

For example, the plurality of pad electrodes PE and the plurality of second connection lines 122 can be integrally formed. Therefore, the plurality of pad electrodes PE and the plurality of second connection lines 122 can be formed of the same material, but are not limited thereto.

According to aspects of the present disclosure, the passivation layer 216 can be disposed in the active area AA, the first non-active area NA1, and the second non-active area NA2 and can be disposed on the second protection layer 113b in the second non-active area NA2. Therefore, the passivation layer 216 can be disposed to cover not only the plurality of pad electrodes PE disposed on the second protection layer 113b in the second non-active area NA2, but also the plurality of second connection lines 122 disposed on the same layer as the plurality of pad electrodes PE. Accordingly, the passivation layer 216 can reduce permeation of the moisture or impurities introduced not only to the plurality of pad electrodes PE, but also to the plurality of second connection lines 122.

For example, in the display apparatus according to another example embodiment of the present disclosure, an organic insulating layer may not be disposed between the plurality of pad electrodes PE and the plurality of second connection lines 122. For example, not only the first insulating layer 115a, the second insulating layer 115b, and the third insulating layer 115c which are formed of an organic insulating material, but also the third protection layer 214 can be disposed excluding the second non-active area NA2 in which the plurality of pad electrodes PE is disposed. For example, the first insulating layer 115a, the second insulating layer 115b, the third insulating layer 115c, and the third protection layer 214 which are disposed between the plurality of second connection lines 122 and the plurality of pad electrodes PE can be removed. Therefore, the plurality of second connection lines 122 and the plurality of pad electrodes PE are not connected through the contact hole with the organic insulating layer therebetween, but can be disposed on the same layer, for example, the second protection layer 113b to be directly connected to each other through side contact. Accordingly, in addition to a pressure applied while bonding the flexible circuit board FCB and the plurality of pad electrodes PE, a pressure applied to the plurality of second connection lines 122 by the first insulating layer 115a, the second insulating layer 115b, the third insulating layer 115c, and the third protection layer 214 can be minimized or reduced. Therefore, a pressure margin for bonding the flexible circuit board FCB and the plurality of pad electrodes PE can be ensured while minimizing or reducing the lifting of the plurality of second connection lines 122.

Accordingly, in the display apparatus according to another example embodiment of the present disclosure, the lifting of the plurality of second connection lines 122 is minimized or reduced to suppress bubbles and permeation of moisture or oxygen through the lifted space can be minimized or reduced. Therefore, the reliability of the display apparatus can be improved. Further, a stronger pressure is applied to bond the flexible circuit board FCB and the plurality of pad electrodes PE by ensuring a pressure margin for bonding the flexible circuit board FCB and the plurality of pad electrodes PE. Therefore, the electrical connection between the plurality of pad electrodes PE and the flexible circuit board FCB can be improved.

Further, in the display apparatus according to another example embodiment of the present disclosure, the plurality of pad electrodes PE and the plurality of second connection lines 122 are disposed on the same layer. Therefore, the passivation layer 216 can be disposed so as to cover not only the plurality of pad electrodes PE, but also the plurality of second connection lines 122. Therefore, not only the plurality of pad electrodes PE, but also the plurality of second connection lines 122 can be effectively protected from the permeation of the oxygen or moisture from the outside.

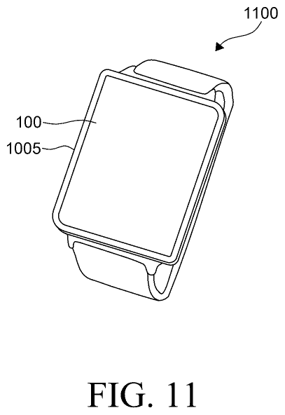

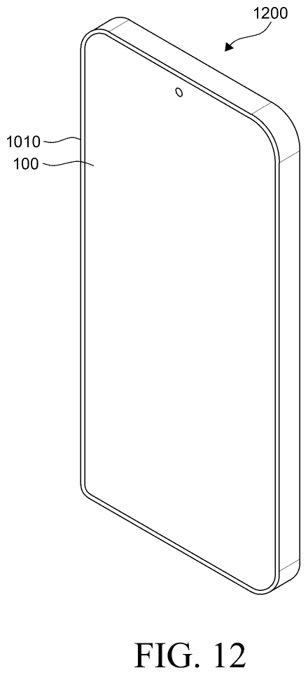

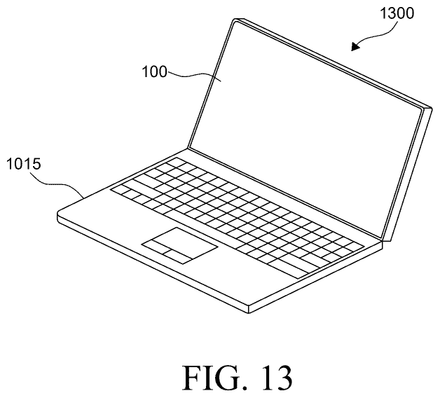

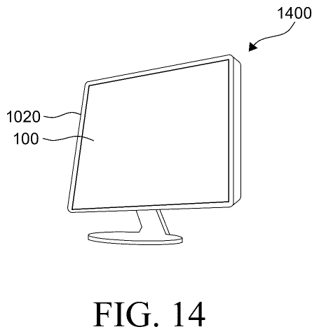

FIGS. 11 to 14 are views illustrating devices to which a display apparatus according to example embodiments of the present disclosure is applied.

Referring to FIGS. 11 to 14, the display apparatus 1000 according to the example embodiments of the present disclosure can be included in various apparatuses or electronic apparatuses. For example, referring to FIGS. 11 to 14, various electronic apparatuses can include a wearable device 1100, a mobile device 1200, a laptop 1300, and a monitor, or TV 1400, but the example embodiments of the present disclosure are not limited thereto.

Each of the wearable device 1100, the mobile device 1200, the laptop 1300, and the monitor or the TV 1400 can include case parts 1005, 1010, 1015, and 1020 and the display panel 100 and 200 and the display apparatus 1000 according to the example embodiments of the present disclosure described in FIGS. 1 to 10.

For example, the display apparatus according to an example embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.

The example embodiments of the present disclosure can also be described as follows:

According to an aspect of the present disclosure, there is provided a display apparatus. The display apparatus includes a substrate which has an active area and a non-active area including a first non-active area enclosing the active area, a bending area extending from the first non-active area, and a second non-active area extending from the bending area and having a plurality of pad electrodes disposed therein, a pixel driving circuit which is disposed on the substrate and is electrically connected to the plurality of pad electrodes, a plurality of insulating layers disposed on the pixel driving circuit and a plurality of micro LEDs which is disposed on the plurality of insulating layers in the active area to be electrically connected to the pixel driving circuit. The plurality of insulating layers is disposed in an area other than the second non-active area.

The display apparatus can further include a first protection layer which is disposed in the active area and at least a part of the non-active area and is disposed so as to enclose the pixel driving circuit, a second protection layer which is disposed on the first protection layer, a third protection layer which is disposed on the pixel driving circuit and the second protection layer, and a plurality of connection lines which is electrically connected to the pixel driving circuit. The plurality of connection lines can include a first connection line which is disposed on the second protection layer in the active area and a second connection line which is at least partially disposed on the second protection layer in the second non-active area.

The third protection layer can be entirely disposed in the first non-active area, the bending area, and the second non-active area of the non-active area and the plurality of pad electrodes can be disposed on the third protection layer.

The plurality of pad electrodes can be directly connected to the second connection line through a contact hole of the third protection layer.

The display apparatus can further include a passivation layer disposed on the plurality of connection lines. The passivation layer can be disposed on the plurality of insulating layers in the active area and can be disposed on the third protection layer in the second non-active area to cover a part of the plurality of pad electrodes.

The third protection layer can be disposed in an area other than the second non-active area.

The plurality of pad electrodes can be disposed on the same layer as the second connection line to be directly connected to the second connection line.

The display apparatus can further include a passivation layer disposed on the plurality of connection lines. The passivation layer can be disposed on the plurality of insulating layers in the active area and can be disposed on the second protection layer in the second non-active area to cover a part of the second connection line and the plurality of pad electrodes.

The insulating layer can include a first insulating layer, a second insulating layer on the first insulating layer, and a third insulating layer on the second insulating layer and an end of the second insulating layer can be disposed between the first insulating layer and the second insulating layer in the bending area.

The third protection layer can be entirely disposed in the first non-active area, the bending area, and the second non-active area of the non-active area and ends of the first insulating layer and ends of the third insulating layer can be disposed in the bending area to be in contact with the third protection layer.

The third protection layer can be disposed in an area other than the second non-active area and ends of the first insulating layer and ends of the third insulating layer can be disposed in the bending area to be in contact with the second connection line.

The plurality of micro LEDs can include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus can further include a first electrode which is disposed below the plurality of micro LEDs to electrically connect the pixel driving circuit and the anode electrodes of the plurality of micro LEDs and a solder pattern which is disposed between the first electrode and the anode electrode. The first electrode and the anode electrode can be electrically connected by eutectic bonding using the solder pattern.

According to another aspect of the present disclosure, there is provided a display apparatus. The display apparatus includes a substrate which has an active area and a non-active area including a first non-active area enclosing the active area, a bending area extending from the first non-active area, and a second non-active area extending from the bending area and having a plurality of pad electrodes disposed therein, a pixel driving circuit which is disposed on the substrate and is electrically connected to the plurality of pad electrodes, a plurality of insulating layers disposed on the pixel driving circuit, a plurality of micro LEDs which is disposed on the plurality of insulating layers in the active area to be electrically connected to the pixel driving circuit and a plurality of connection lines which is disposed on the pixel driving circuit and is electrically connected to the pixel driving circuit. The plurality of insulating layers is disposed in an area other than the second non-active area.

The plurality of connection lines can include a first connection line including a 1-1-th connection line which connects the pixel driving circuit and the plurality of micro LEDs in the active area and is disposed on a different layer, a 1-2-th connection line on the 1-1-th connection line, a 1-3-th connection line on the 1-2-th connection line, and a 1-4-th connection line on the 1-3-th connection line and a second connection line which is at least partially disposed in the second non-active area and connects the pixel driving circuit and the plurality of pad electrodes.

At least a part of the second connection line can be disposed on the same layer as the 1-1-th connection line and the plurality of pad electrodes can be disposed on the same layer as the 1-2-th connection line.

The plurality of pad electrodes can be disposed on the same layer as the second connection line and at least a part of the second connection line and the plurality of pad electrodes can be disposed on the same layer as the 1-1-th connection line.

The plurality of pad electrodes can be disposed to be lower than the 1-3-th connection line and the 1-4-th connection line.

Each of the plurality of micro LEDs can include an anode electrode, a first semiconductor layer disposed on the anode electrode, an active layer disposed on the first semiconductor layer, a second semiconductor layer disposed on the active layer, and a cathode electrode disposed on the second semiconductor layer and each of the plurality of micro LEDs can have a vertical type structure.

The display apparatus can further include a first electrode disposed below the plurality of micro LEDs and a solder pattern which is disposed between the first electrode and the anode electrode. The anode electrode is bonded to the first electrode by eutectic bonding using the solder pattern.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display apparatus comprising:
a substrate including an active area and a non-active area, wherein the non-active area includes a first non-active area adjacent to the active area, a bending area extending from the first non-active area, and a second non-active area extending from the bending area and having a plurality of pad electrodes disposed therein;
a pixel driving circuit disposed on the substrate and electrically connected to the plurality of pad electrodes;
a plurality of insulating layers disposed on the pixel driving circuit; and
a plurality of micro light emitting diodes (LEDs) disposed on the plurality of insulating layers in the active area to be electrically connected to the pixel driving circuit,
wherein the plurality of insulating layers is disposed in an area other than the second non-active area.

2. The display apparatus according to claim 1, further comprising:
a first protection layer disposed in the active area and at least a part of the non-active area, and disposed to enclose at least a part of the pixel driving circuit;
a second protection layer disposed on the first protection layer;
a third protection layer disposed on the pixel driving circuit and the second protection layer; and
a plurality of connection lines electrically connected to the pixel driving circuit,
wherein the plurality of connection lines includes:
a first connection line disposed on the second protection layer in the active area; and
a second connection line at least partially disposed on the second protection layer in the second non-active area.

3. The display apparatus according to claim 2, wherein the third protection layer is entirely disposed in the first non-active area, the bending area, and the second non-active area of the non-active area, and
wherein the plurality of pad electrodes is disposed on the third protection layer.

4. The display apparatus according to claim 3, wherein the plurality of pad electrodes is directly connected to the second connection line through a contact hole of the third protection layer.

5. The display apparatus according to claim 3, further comprising:
a passivation layer disposed on the plurality of connection lines,
wherein the passivation layer is disposed on the plurality of insulating layers in the active area and is disposed on the third protection layer in the second non-active area to cover a part of the plurality of pad electrodes.

6. The display apparatus according to claim 2, wherein the third protection layer is disposed in an area other than the second non-active area.

7. The display apparatus according to claim 6, wherein the plurality of pad electrodes is disposed on a same layer as the second connection line to be directly connected to the second connection line.

8. The display apparatus according to claim 6, further comprising:
a passivation layer disposed on the plurality of connection lines,
wherein the passivation layer is disposed on the plurality of insulating layers in the active area and is disposed on the second protection layer in the second non-active area to cover a part of the second connection line and the plurality of pad electrodes.

9. The display apparatus according to claim 2, wherein the insulating layer includes a first insulating layer, a second insulating layer on the first insulating layer, and a third insulating layer on the second insulating layer, and
wherein an end of the second insulating layer is disposed between the first insulating layer and the second insulating layer in the bending area.

10. The display apparatus according to claim 9, wherein the third protection layer is entirely disposed in the first non-active area, the bending area, and the second non-active area of the non-active area, and
wherein ends of the first insulating layer and ends of the third insulating layer are disposed in the bending area to be in contact with the third protection layer.

11. The display apparatus according to claim 9, wherein the third protection layer is disposed in an area other than the second non-active area, and ends of the first insulating layer and ends of the third insulating layer are disposed in the bending area to be in contact with the second connection line.

12. The display apparatus according to claim 1, wherein the plurality of micro LEDs includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

13. The display apparatus according to claim 12, further comprising:
a first electrode disposed below the plurality of micro LEDs to electrically connect the pixel driving circuit and the anode electrodes of the plurality of micro LEDs; and
a solder pattern disposed between the first electrode and the anode electrode,
wherein the first electrode and the anode electrode are electrically connected by eutectic bonding using the solder pattern.

14. A display apparatus comprising:
a substrate including an active area and a non-active area, wherein the non-active area includes a first non-active area adjacent to the active area, a bending area extending from the first non-active area, and a second non-active area extending from the bending area and having a plurality of pad electrodes disposed therein;
a pixel driving circuit disposed on the substrate and electrically connected to the plurality of pad electrodes;
a plurality of insulating layers disposed on the pixel driving circuit;
a plurality of micro light emitting diodes (LEDs) disposed on the plurality of insulating layers in the active area to be electrically connected to the pixel driving circuit; and
a plurality of connection lines disposed on the pixel driving circuit and electrically connected to the pixel driving circuit,
wherein the plurality of insulating layers is disposed in an area other than the second non-active area.

15. The display apparatus according to claim 14, wherein the plurality of connection lines includes:
a first connection line including a 1-1-th connection line which connects the pixel driving circuit and the plurality of micro LEDs in the active area and is disposed on a different layers, a 1-2-th connection line on the 1-1-th connection line, a 1-3-th connection line on the 1-2-th connection line, and a 1-4-th connection line on the 1-3-th connection line; and
a second connection line at least partially disposed in the second non-active area and connecting the pixel driving circuit and the plurality of pad electrodes.

16. The display apparatus according to claim 15, wherein at least a part of the second connection line is disposed on a same layer as the 1-1-th connection line and the plurality of pad electrodes is disposed on a same layer as the 1-2-th connection line.

17. The display apparatus according to claim 15, wherein the plurality of pad electrodes is disposed on a same layer as the second connection line and at least a part of the second connection line and the plurality of pad electrodes are disposed on a same layer as the 1-1-th connection line.

18. The display apparatus according to claim 15, wherein the plurality of pad electrodes is disposed to be lower than the 1-3-th connection line and the 1-4-th connection line.

19. The display apparatus according to claim 14, wherein each of the plurality of micro LEDs includes:
an anode electrode,
a first semiconductor layer disposed on the anode electrode,
an active layer disposed on the first semiconductor layer,
a second semiconductor layer disposed on the active layer, and
a cathode electrode disposed on the second semiconductor layer, and
wherein each of the plurality of micro LEDs has a vertical type structure.

20. The display apparatus according to claim 19, further comprising:
a first electrode disposed below the plurality of micro LEDs; and
a solder pattern disposed between the first electrode and the anode electrode,
wherein the anode electrode is bonded to the first electrode by eutectic bonding using the solder pattern.
